(19) United States
(12) Patent Application Publication
(10) Pub. No.: US 2025/0105133 A1
(43) Pub. Date: Mar. 27, 2025

(54) SEMICONDUCTOR PACKAGE INCLUDING INSULATING MATERIAL

(71) Applicant: Samsung Electronics Co., Ltd., Suwon-si (KR)

(72) Inventors: Jinyoung KIM, Suwon-si (KR); Okseon YOON, Suwon-si (KR); Jiyoung YOON, Suwon-si (KR); Kiseok KIM, Suwon-si (KR); Jihye SHIM, Suwon-si (KR)

(73) Assignee: Samsung Electronics Co., Ltd., Suwon-si (KR)

(21) Appl. No.: 18/828,196

(22) Filed: Sep. 9, 2024

(30) Foreign Application Priority Data
Sep. 25, 2023 (KR) 10-2023-0128480
Nov. 2, 2023 (KR) 10-2023-0150284

(51) Int. Cl. H01L 23/498; H01L 23/00; H01L 23/31; H01L 25/03

(52) U.S. Cl. CPC H01L 23/49894; H01L 23/49822; H01L 23/562; H01L 24/24; H01L 25/03; H01L 23/3107; H01L 23/49816; H01L 24/16; H01L 24/32; H01L 24/73; H01L 2224/16227; H01L 2224/24146; H01L 2224/32225; H01L 2224/73204; H01L 2224/73259; H01L 2224/73267

(57) ABSTRACT

A semiconductor package includes a redistribution structure including a redistribution layer including copper (Cu) and an insulating layer surrounding the redistribution layer, a semiconductor chip mounted on the redistribution structure and including connection pads, internal connection terminals between the redistribution structure and the semiconductor chip electrically connecting the redistribution layer to the connection pads, external connection terminals attached under the redistribution structure and electrically connected to the redistribution layer, and an encapsulant configured to surround the semiconductor chip and the internal connection terminals on the redistribution structure. The insulating layer includes an insulating material of which K is 20 to 100 in a TC index according to equation below.

$$K = \frac{{U}_{T}}{( {α}_{1} - {α}_{2} ) \times Δ T \times E} \qquad [ TC INDEX ]$$

### CROSS-REFERENCE TO RELATED APPLICATION

This application is based on and claims priority under 35 U.S.C. § 119 to Korean Patent Application Nos. 10-2023-0128480, filed on Sep. 25, 2023, and 10-2023-0150284, filed on Nov. 2, 2023 in the Korean Intellectual Property Office, the disclosures of which are incorporated by reference herein in their entireties.

### BACKGROUND

The inventive concepts relate to semiconductor packages, and more particularly, to semiconductor packages including an insulating material forming a redistribution structure.

Recently, the demand for portable electronic devices has rapidly increased in the electronic product market, and as a result, miniaturization and weight reduction of electronic components mounted on portable electronic devices are continuously required. Although overall thickness of semiconductor packages is decreasing in order to miniaturize and lighten electronic components, demands for increased memory capacity continue to increase. Accordingly, wafer level packages have been used to efficiently arrange semiconductor chips within a limited structure of a semiconductor package.

### SUMMARY

The inventive concepts relate to semiconductor packages with improved reliability by forming an insulating layer included in a redistribution structure of an insulating material capable of preventing or reducing physical damage.

The problems to be solved by the technical ideas of the inventive concepts are not limited to the above-mentioned problems, and other problems not mentioned will be clearly understood by those skilled in the art from the following description.

According to some aspects of the inventive concepts, there is provided a semiconductor package including a first redistribution structure including a plurality of first redistribution patterns having a plurality of first bottom surface connection pads and a plurality of first top surface connection pads and a first redistribution insulating layer surrounding the plurality of first redistribution patterns, a first semiconductor chip mounted in a first chip mounting region on the first redistribution structure, a plurality of first solder bumps attached to the plurality of first bottom surface connection pads under the first redistribution structure, a second redistribution structure on the first semiconductor chip and the first redistribution structure and including a plurality of second redistribution patterns having a plurality of second bottom surface connection pads and a plurality of second top surface connection pads and a second redistribution insulating layer surrounding the plurality of second redistribution patterns, a second semiconductor chip mounted in a second chip mounting region on the second redistribution structure, a plurality of second solder bumps attached to the plurality of second top surface connection pads between the second redistribution structure and the second semiconductor chip, a plurality of conductive posts around the first semiconductor chip to connect some of the plurality of first top surface connection pads to some of the plurality of second bottom surface connection pads, and an encapsulant configured to fill a space between the first redistribution structure and the second redistribution structure and to surround the plurality of conductive posts and the first semiconductor chip. Each of the plurality of first redistribution patterns and the plurality of second redistribution patterns is formed of a conductive material, and wherein each of the first redistribution insulating layer and the second redistribution insulating layer is formed of an insulating material satisfying that K is 20 to 100 in a TC index below.

$$K = \frac{{U}_{T}}{( {α}_{1} - {α}_{2} ) \times Δ T \times E} \qquad [ TC INDEX ]$$

wherein, U_{T} refers to toughness of the insulating material, α₁ refers to a thermal expansion coefficient of the insulating material, α₂ refers to a thermal expansion coefficient of the conductive material surrounded by the insulating material, ΔT refers to a temperature change, and E refers to an elastic modulus of the insulating material.

According to some aspects of the inventive concepts, there is provided a semiconductor package including a redistribution structure including a redistribution layer including copper (Cu) and an insulating layer surrounding the redistribution layer, a semiconductor chip mounted on the redistribution structure and including connection pads, internal connection terminals between the redistribution structure and the semiconductor chip configured to electrically connect the redistribution layer to the connection pads, external connection terminals attached under the redistribution structure and electrically connected to the redistribution layer, and an encapsulant configured to surround the semiconductor chip and the internal connection terminals on the redistribution structure. The insulating layer is formed of an insulating material satisfying that K is 20 to 100 in a TC index below.

$$K = \frac{{U}_{T}}{( {α}_{1} - {α}_{2} ) \times Δ T \times E} \qquad [ TC INDEX ]$$

wherein, U_{T} refers to toughness of an insulating material, α₁ refers to a thermal expansion coefficient of an insulating material, α₂ refers to a thermal expansion coefficient of copper (Cu), ΔT refers to a temperature change, and E refers to an elastic modulus of an insulating material.

According to some aspects of the inventive concepts, there is provided a semiconductor package including a redistribution structure including a first insulating layer, at least one a second insulating layer on the first insulating layer, and a plurality of redistribution layers on the first insulating layer and the at least one the second insulating layer, the plurality of redistribution layers configured to electrically connect to one another, each of the plurality of redistribution layers includes a conductive material, a semiconductor chip mounted on the redistribution structure and including connection pads, internal connection terminals between the redistribution structure and the semiconductor chip configured to electrically connect the plurality of redistribution layers to the connection pads, external connection terminals attached under the redistribution structure and electrically connected to the plurality of redistribution layers, and an encapsulant configured to surround the semiconductor chip and the internal connection terminals on the redistribution structure. Each of the first insulating layer and at least one the second insulating layer is formed of an insulating material satisfying that K is 20 to 100 in a TC index below.

$$K = \frac{{U}_{T}}{( {α}_{1} - {α}_{2} ) \times Δ T \times E} \times \frac{{d}_{1}}{{d}_{2}} \qquad [ TC INDEX ]$$

U_{T} refers to toughness of an insulating material, α₁ refers to a thermal expansion coefficient of an insulating material, α₂ refers to a thermal expansion coefficient of a conductive material surrounded by an insulating material, ΔT refers to a temperature change, E refers to an elastic modulus of an insulating material, d₁ refers to a vertical distance from a bottom surface of a semiconductor chip to top surfaces of external connection terminals, and d₂ refers to a vertical distance from a bottom surface of a semiconductor chip to a bottom surface of a first insulating layer or a second insulating layer.

### BRIEF DESCRIPTION OF THE DRAWINGS

Example embodiments will be more clearly understood from the following detailed description taken in conjunction with the accompanying drawings in which:

FIG. 1 is a cross-sectional view illustrating main components of a semiconductor package according to some example embodiments;

FIG. 2 is an enlarged cross-sectional view illustrating a portion AA of FIG. 1;

FIG. 3 is a scanning electron micrograph illustrating a peripheral region of an under-bump metal of FIG. 2;

FIGS. 4 to 6 are graphs illustrating a degree of crack occurrence according to various physical properties of an insulating material of an insulating layer included in a redistribution structure;

FIG. 7 is a cross-sectional view illustrating main components of a semiconductor package according to some example embodiments;

FIG. 8 is an enlarged cross-sectional view illustrating a portion BB of FIG. 7;

FIG. 9 is a flowchart illustrating a method of manufacturing a semiconductor package according to some example embodiments;

FIGS. 10 to 22 are cross-sectional views illustrating a method of manufacturing a semiconductor package according to some example embodiments in a process order; and

FIG. 23 is a block diagram schematically illustrating a configuration of a semiconductor package according to some example embodiments.

### DETAILED DESCRIPTION

Hereinafter, example embodiments of the inventive concepts will be described in detail with reference to the accompanying drawings.

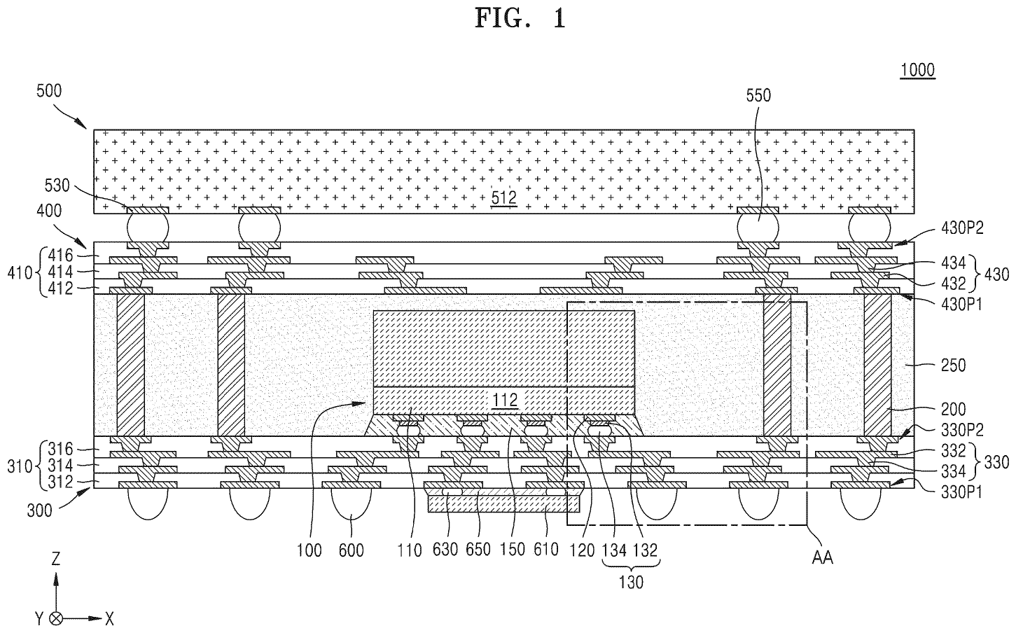

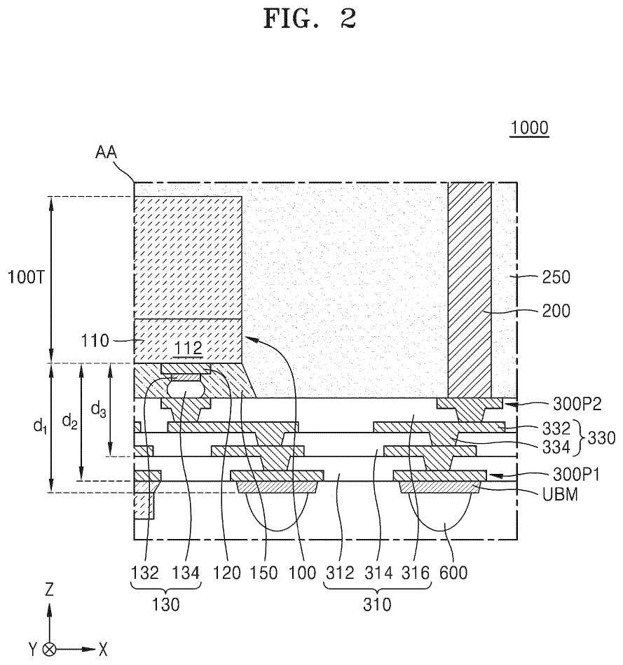

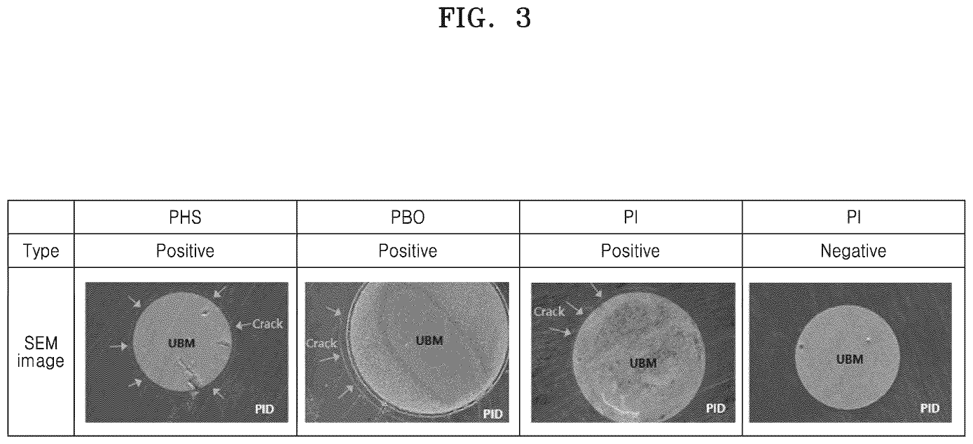

FIG. 1 is a cross-sectional view illustrating main components of a semiconductor package 1000 according to some example embodiments. FIG. 2 is an enlarged cross-sectional view illustrating a portion AA of FIG. 1. FIG. 3 is a scanning electron micrograph illustrating a peripheral region of an under-bump metal of FIG. 2.

Referring to FIGS. 1 to 3, the semiconductor package 1000 may include a first semiconductor chip 100, a plurality of conductive posts 200 arranged around the first semiconductor chip 100, a first redistribution structure 300 arranged below the first semiconductor chip 100, a second redistribution structure 400 arranged above the first semiconductor chip 100, and a second semiconductor chip 500 arranged above the second redistribution structure 400.

The semiconductor package 1000 may have a package-on-package (POP) structure. For example, the semiconductor package 1000 may include a fan out semiconductor package in which a horizontal width and a horizontal area of the first redistribution structure 300 are greater than a horizontal width and a horizontal area of the first semiconductor chip 100. In some example embodiments, the semiconductor package 1000 may include a fan out wafer level package (FOWLP) or a fan out panel level package (FOPLP).

In some example embodiments, the first redistribution structure 300 and the second redistribution structure 400 may be formed by a redistribution process. Here, the first redistribution structure 300 and the second redistribution structure 400 may be referred to as a lower redistribution structure and an upper redistribution structure, respectively.

The first redistribution structure 300 may include a first redistribution insulating layer 310 and a plurality of first redistribution patterns 330. The first redistribution insulating layer 310 may surround the plurality of first redistribution patterns 330. In some example embodiments, the first redistribution structure 300 may include a plurality of stacked first redistribution insulating layers 310. For example, the plurality of first redistribution insulating layers 310 may sequentially include a first insulating layer 312, a second insulating layer 314, and a third insulating layer 316. However, the inventive concepts are not limited thereto. The first insulating layer 312, the second insulating layer 314, and the third insulating layer 316 may be formed of the same material or different materials. The first redistribution insulating layer 310 may be formed of, for example, a photo-imageable dielectric (PID) material. For example, at least one of the first insulating layer 312, the second insulating layer 314, and the third insulating layer 316 may include insulating materials with different K values in TC index 1 or TC index 2 below, which will be described in detail later. In some example embodiments, each of the first insulating layer 312, the second insulating layer 314, and the third insulating layer 316 (and, for example, additional insulating layers in the first redistribution insulating layers 310) may have a thickness of about or exactly 3 μm to about or exactly 10 μm.

The plurality of first redistribution patterns 330 may include a plurality of first redistribution line patterns 332 and a plurality of first redistribution vias 334. The plurality of first redistribution patterns 330 may include, for example, a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Rc), beryllium (Be), gallium (Ga), or ruthenium (Ru) and/or an alloy thereof. However, the inventive concepts are not limited thereto.

The plurality of first redistribution line patterns 332 may be arranged on at least one of top and bottom surfaces of the first redistribution insulating layer 310. For example, when the first redistribution structure 300 includes the plurality of stacked first redistribution insulating layers 310, the plurality of first redistribution line patterns 332 may be arranged on a top surface of the uppermost first redistribution insulating layer 310 and a bottom surface of the lowermost first redistribution insulating layer 310, and between adjacent first redistribution insulating layers 310.

The plurality of first redistribution vias 334 may penetrate the first redistribution insulating layer 310 to be connected to some of the plurality of first redistribution line patterns 332. In some example embodiments, each of the plurality of first redistribution vias 334 may have a tapered shape extending from a bottom to a top with an increasing horizontal width.

In some example embodiments, some of the plurality of first redistribution line patterns 332 may be formed together with some of the plurality of first redistribution vias 334 to be integrated. For example, the first redistribution line pattern 332 and the first redistribution via 334 contacting a bottom surface of the first redistribution line pattern 332 may be formed together to be integrated.

Among the plurality of first redistribution patterns 330, some arranged adjacent to a bottom surface of the first redistribution structure 300 may be referred to as a plurality of first bottom surface connection pads 330P1, and some arranged adjacent to a top surface of the first redistribution structure 300 may be referred to as a plurality of first top surface connection pads 330P2. That is, the plurality of first bottom surface connection pads 330P1 may include some arranged adjacent to the bottom surface of the first redistribution structure 300 among the plurality of first redistribution line patterns 332, and the plurality of first top surface connection pads 330P2 may include some arranged adjacent to the top surface of the first redistribution structure 300 among the plurality of first redistribution line patterns 332.

A plurality of external connection terminals 600 may be attached to the plurality of first bottom surface connection pads 330P1. The plurality of external connection terminals 600 may connect the semiconductor package 1000 to the outside. In some example embodiments, the plurality of external connection terminals 600 may include solder bumps or solder balls. In some example embodiments, a plurality of chip connection members 130 may be attached to some of the plurality of first top surface connection pads 330P2, and the plurality of conductive posts 200 may be attached to others of the plurality of first top surface connection pads 330P2.

In some example embodiments, a plurality of under-bump metals UBM may be arranged between the plurality of first bottom surface connection pads 330P1 and the plurality of external connection terminals 600. That is, the plurality of under-bump metals UBM may be arranged under the plurality of first bottom surface connection pads 330P1, and the plurality of external connection terminals 600 may be arranged under the plurality of under-bump metals UBM. Accordingly, the plurality of under-bump metals UBM may be arranged to protrude downward from the lowermost surface of the first redistribution insulating layer 310.

In some example embodiments, the plurality of external connection terminals 600 may be attached to some of the plurality of first bottom surface connection pads 330P1, and a passive element 610 may be attached to others of the plurality of first bottom connection pads 330P1.

The plurality of external connection terminals 600 may be formed on the top surface of the first redistribution structure 300. The plurality of external connection terminals 600 may include, for example, solder balls, conductive bumps, conductive paste, a ball grid array (BGA), a lead grid array (LGA), a pin grid array (PGA), or a combination thereof.

The passive element 610 may include at least one selected from a resistor, a capacitor, an inductor, a thermistor, an oscillator, a ferrite bead, an antenna, and a varistor. For example, the passive element 610 may include a multilayer ceramic capacitor (MLCC), a low inductance chip capacitor (LICC), a land side capacitor (LSC), or an integrated passive device (IPD). However, the inventive concepts are not limited thereto.

An external underfill layer 650 may surround sidewalls of solder bumps 630 arranged under the passive element 610 and may fill a gap between the solder bumps 630 adjacent to each other. In a process of electrically connecting the passive element 610 to the solder bumps 630, a gap may be formed between the passive element 610 and the solder bumps 630. Because the gap may cause a problem in reliability of connection between the passive element 610 and the solder bumps 630, the external underfill layer 650 may be injected and cured to reinforce the connection.

The passive element 610 is more stably fixed onto the solder bumps 630 by the external underfill layer 650, and despite a difference in a thermal expansion coefficient between the passive element 610 and the solder bumps 630, the passive element 610 may not be electrically separated from the solder bumps 630.

The plurality of first top surface connection pads 330P2 may be arranged on the top surface of the first redistribution insulating layer 310. For example, when the first redistribution structure 300 includes the plurality of stacked first redistribution insulating layers 310, the plurality of first top surface connection pads 330P2 may be arranged on the top surface of the uppermost first redistribution insulating layer 310.

At least one first semiconductor chip 100 may be mounted on the first redistribution structure 300. That is, the first semiconductor chip 100 may include a single chip or a plurality of chips. The first semiconductor chip 100 may include a semiconductor substrate 110 having an active surface and an inactive surface facing each other, a semiconductor device 112 formed on the active surface of the semiconductor substrate 110, and a plurality of chip pads 120 arranged on a first surface of the first semiconductor chip 100. For example, the first semiconductor chip 100 may have a thickness 100T of about or exactly 150 μm to about or exactly 1500 μm.

Here, the first surface and a second surface of the first semiconductor chip 100 face each other, and the second surface of the first semiconductor chip 100 means the inactive surface of the semiconductor substrate 110. Because the active surface of the semiconductor substrate 110 is adjacent to the first surface of the first semiconductor chip 100, illustration distinguishing the active surface of the semiconductor substrate 110 from the first surface of the first semiconductor chip 100 is omitted.

In some example embodiments, the first semiconductor chip 100 has a face-down arrangement in which the first surface faces the first redistribution structure 300 and may be mounted on the top surface of the first redistribution structure 300. In this case, the first surface of the first semiconductor chip 100 may be referred to as a bottom surface of the first semiconductor chip 100, and the second surface of the first semiconductor chip 100 may be referred to as a top surface of the first semiconductor chip 100.

The plurality of chip connection members 130 may be interposed between the plurality of chip pads 120 of the first semiconductor chip 100 and some of the plurality of first top surface connection pads 330P2 of the first redistribution structure 300. For example, each of the plurality of chip connection members 130 may be a solder ball or a micro-bump. The first semiconductor chip 100 may be electrically connected to the plurality of first redistribution patterns 330 of the first redistribution structure 300 through the plurality of chip connection members 130. The plurality of chip connection members 130 may include a plurality of bump layers 132 arranged on the plurality of chip pads 120 and a plurality of internal connection terminals 134 covering the plurality of bump layers 132. The plurality of chip connection members 130 may be formed of, for example, Cu, Al, silver (Ag), Sn, gold (Au), and/or solder. However, the inventive concepts are not limited thereto.

The semiconductor substrate 110 may include, for example, a semiconductor material such as silicon (Si) or germanium (Ge). Alternatively, the semiconductor substrate 110 may include a compound semiconductor material such as silicon carbide (SiC), gallium arsenide (GaAs), indium arsenide (InAs), and indium phosphide (InP). The semiconductor substrate 110 may include a well doped with impurities, which is a conductive region. The semiconductor substrate 110 may have various device isolation structures such as a shallow trench isolation (STI) structure.

The semiconductor device 112 including a plurality of various types of individual devices may be formed on the active surface of the semiconductor substrate 110. The plurality of individual devices may be electrically connected to the conductive region of the semiconductor substrate 110. The semiconductor device 112 may further include a conductive wiring or a conductive plug electrically connecting the plurality of individual devices to the conductive region of the semiconductor substrate 110. In addition, each of the plurality of individual devices may be electrically separated from other neighboring individual devices by an insulating layer.

In some example embodiments, the first semiconductor chip 100 may include a logic element. For example, the first semiconductor chip 100 may include a central processing unit (CPU) chip, a graphics processing unit (GPU) chip, or an application processor (AP) chip. In some example embodiments, when the semiconductor package 1000 includes a plurality of first semiconductor chips 100, one of the plurality of first semiconductor chips 100 may include the CPU chip, the GPU chip, or the AP chip, and the other may include a memory semiconductor chip including a memory device.

For example, the memory device may include a non-volatile memory device such as flash memory, phase-change random access memory (PRAM), magnetoresistive random access memory (MRAM), ferroelectric random access memory (FeRAM), or resistive random access memory (RRAM). In some example embodiments, the memory device may include a volatile memory device such as dynamic random access memory (DRAM) or static random access memory (SRAM).

The second redistribution structure 400 may include a second redistribution insulating layer 410 and a plurality of second redistribution patterns 430. The second redistribution insulating layer 410 may surround the plurality of second redistribution patterns 430. In some example embodiments, the second redistribution structure 400 may include a plurality of stacked second redistribution insulating layers 410. For example, the plurality of second redistribution insulating layers 410 may sequentially include a fourth insulating layer 412, a fifth insulating layer 414, and a sixth insulating layer 416. However, the inventive concepts are not limited thereto. The fourth insulating layer 412, the fifth insulating layer 414, and the sixth insulating layer 416 may be formed of the same material or different materials. The second redistribution insulating layer 410 may be formed of, for example, a PID material. For example, at least one of the fourth insulating layer 412, the fifth insulating layer 414, and the sixth insulating layer 416 may include insulating materials with different K values in TC index 1 or TC index 2 below, which will be described in detail later. In some example embodiments, a fourth insulating layer 412, a fifth insulating layer 414, and a sixth insulating layer 416 (and, for example, additional insulating layers in the plurality of second redistribution insulating layers 410) each have a thickness of about or exactly 3 μm to about or exactly 10 μm.

In some example embodiments, the second redistribution structure 400 may include a plurality of stacked second redistribution insulating layers 410. The plurality of second redistribution patterns 430 may include a plurality of second redistribution line patterns 432 and a plurality of second redistribution vias 434. The plurality of second redistribution patterns 430 may include a metal or a metal alloy. In some example embodiments, the plurality of second redistribution patterns 430 may be formed by stacking a metal or a metal alloy on a seed layer.

The plurality of second redistribution line patterns 432 may be arranged on at least one of top and bottom surfaces of the second redistribution insulating layer 410. For example, when the second redistribution structure 400 includes the plurality of stacked second redistribution insulating layers 410, the plurality of second redistribution line patterns 432 may be arranged on a top surface of the uppermost second redistribution insulating layer 410 and a bottom surface of the lowermost second redistribution insulating layer 410, and between adjacent second redistribution insulating layers 410.

Among the plurality of second redistribution patterns 430, some arranged adjacent to a bottom surface of the second redistribution structure 400 may be referred to as a plurality of second bottom surface connection pads 430P1, and some arranged adjacent to a top surface of the second redistribution structure 400 may be referred to as a plurality of second top surface connection pads 430P2. That is, the plurality of second bottom surface connection pads 430P1 may include some arranged adjacent to the bottom surface of the second redistribution structure 400 among the plurality of second redistribution line patterns 432, and the plurality of second top surface connection pads 430P2 may include some arranged adjacent to the top surface of the second redistribution structure 400 among the plurality of second redistribution line patterns 432. In some example embodiments, the plurality of second bottom surface connection pads 430P1 may be arranged adjacent to the bottom surface of the second redistribution structure 400 among the plurality of second redistribution vias 434.

The second semiconductor chip 500 may include a second semiconductor device 512 and a plurality of second pads 530. The second semiconductor chip 500 may be electrically connected to the second redistribution structure 400 by a plurality of internal connection terminals 550 interposed between the plurality of second pads 530 and the plurality of second top surface connection pads 430P2. The second semiconductor chip 500 may be mounted on the second redistribution structure 400 so that the plurality of second pads 530 face the second redistribution structure 400.

In some example embodiments, the second semiconductor chip 500 may be electrically connected to the plurality of first redistribution patterns 330 of the first redistribution structure 300 through a plurality of internal connection terminals 550 attached to the plurality of second pads 530, the plurality of second redistribution patterns 430, and the plurality of conductive posts 200.

In some example embodiments, the second semiconductor device 512 may include a memory device. For example, the memory device may include a non-volatile memory device such as flash memory, PRAM, MRAM, FeRAM, or RRAM. In some example embodiments, the memory device may include a volatile memory device such as DRAM or SRAM.

The plurality of second bottom surface connection pads 430P1 may be arranged on a bottom surface of the second redistribution insulating layer 410. For example, when the second redistribution structure 400 includes the plurality of stacked second redistribution insulating layers 410, the plurality of second bottom surface connection pads 430P1 may be arranged on the bottom surface of the lowermost second redistribution insulating layer 410.

The plurality of second top surface connection pads 430P2 may be arranged on a top surface of the second redistribution insulating layer 410. For example, when the second redistribution structure 400 includes the plurality of stacked second redistribution insulating layers 410, the plurality of second top surface connection pads 430P2 may be arranged on the top surface of the uppermost second redistribution insulating layer 410.

The plurality of second redistribution vias 434 may penetrate the second redistribution insulating layer 410 to be connected to some of the plurality of second redistribution line patterns 432. In some example embodiments, some of the plurality of second redistribution line patterns 432 may be formed together with some of the plurality of second redistribution vias 434 to be integrated. For example, the second redistribution line pattern 432 and the second redistribution via 434 contacting a bottom surface of the second redistribution line pattern 432 may be formed together to be integrated.

In some example embodiments, each of the plurality of second redistribution vias 434 may have a tapered shape extending from a top to a bottom with a decreasing horizontal width. That is, the plurality of first redistribution vias 334 and the plurality of second redistribution vias 434 extend in the same direction with decreasing horizontal widths. However, the inventive concepts are not limited thereto.

Here, the first redistribution insulating layer 310, the first redistribution pattern 330, the first redistribution line pattern 332, and the first redistribution via 334 may be referred to as a first insulating layer, a first wiring pattern, a first wiring line pattern, and a first wiring via, respectively. Here, the second redistribution insulating layer 410, the second redistribution pattern 430, the second redistribution line pattern 432, and the second redistribution via 434 may be referred to as a second insulating layer, a second wiring pattern, a second wiring line pattern, and a second wiring via, respectively.

An encapsulant 250 may surround the first semiconductor chip 100 on the top surface of the first redistribution structure 300. The encapsulant 250 may fill a space between the first redistribution structure 300 and the second redistribution structure 400. For example, the encapsulant 250 may include a molding member including an epoxy mold compound (EMC). The encapsulant 250 may further include a filler.

In some example embodiments, an internal underfill layer 150 surrounding the plurality of chip connection members 130 may be interposed between the first semiconductor chip 100 and the first redistribution structure 300. In some example embodiments, the internal underfill layer 150 may fill a space between the first semiconductor chip 100 and the first redistribution structure 300 and may partially cover lower sides of the first semiconductor chip 100. The internal underfill layer 150 may be formed by, for example, a capillary underfill process, and may be formed of, for example, epoxy resin or the like.

In some example embodiments, side surfaces of the first redistribution structure 300, side surfaces of the encapsulant 250, and side surfaces of the second redistribution structure 400 may be aligned with one another in a vertical direction to be coplanar.

The plurality of conductive posts 200 may penetrate the encapsulant 250 to electrically connect the first redistribution structure 300 to the second redistribution structure 400. The encapsulant 250 may surround the plurality of conductive posts 200.

The plurality of conductive posts 200 may be interposed between the first redistribution structure 300 and the second redistribution structure 400 to be apart from the first semiconductor chip 100 in a horizontal direction. For example, the plurality of conductive posts 200 may be apart from the first semiconductor chip 100 in the horizontal direction, and may be arranged around the first semiconductor chip 100 in an outer region of the first redistribution structure 300.

The plurality of conductive posts 200 may be interposed between the plurality of first top surface connection pads 330P2 and the plurality of second bottom surface connection pads 430P1. Bottom surfaces of the plurality of conductive posts 200 may contact the plurality of first top surface connection pads 330P2 of the first redistribution structure 300 to be electrically connected to the plurality of first redistribution patterns 330, and top surfaces of the plurality of conductive posts 200 may contact the plurality of second bottom surface connection pads 430P1 of the second redistribution structure 400 to be electrically connected to the plurality of second redistribution patterns 430. In some example embodiments, the plurality of conductive posts 200 may include Cu or a Cu alloy. However, the inventive concepts are not limited thereto.

The bottom surfaces of the plurality of conductive posts 200 may contact top surfaces of the plurality of first top surface connection pads 330P2, respectively. Top surfaces of the plurality of conductive posts 200 may contact bottom surfaces of the plurality of second bottom surface connection pads 430P1, respectively.

Recently, demands for portable electronic devices are rapidly increasing in the electronic product market, and as a result, miniaturization and weight reduction of electronic components mounted on portable electronic devices are continuously required. Although overall thickness of semiconductor packages is decreasing in order to miniaturize and lighten electronic components, demands for increased memory capacity continue to increase. Therefore, a fan-out wafer level package is being applied to efficiently arrange the first semiconductor chip 100 in a limited structure of the semiconductor package 1000.

According to heat dissipation of the first semiconductor chip 100 in the limited structure of the semiconductor package 1000, in the first redistribution structure 300 constituting the fan-out wafer level package, due to a difference in thermal expansion coefficient between the first redistribution insulating layer 310 as an insulating material and the first redistribution pattern 330 as a conductive material, cracks may occur in the first redistribution insulating layer 310 with a relatively low strength.

Similarly, in the second redistribution structure 400 constituting the fan-out wafer level package, due to a difference in thermal expansion coefficient between the second redistribution insulating layer 410 as an insulating material and the second redistribution pattern 430 as a conductive material, cracks may occur in the second redistribution insulating layer 410 with a relatively low strength.

In this way, in order to solve the problem of cracks, the first redistribution insulating layer 310 and the second redistribution insulating layer 410 are formed of various insulating materials. However, due to the different characteristics of the wide variety of materials forming the semiconductor package 1000, it is difficult to identify the problem in advance.

Accordingly, in some example embodiments a new TC index to minimize the problem of cracks by applying a highly reliable insulating material to the first redistribution insulating layer 310 and the second redistribution insulating layer 410 may be used.

In some example embodiments, each of the first redistribution insulating layer 310 and the second redistribution insulating layer 410 may include an insulating material satisfying that K is 20 or more in TC index 1 below.

$$K = \frac{{U}_{T}}{( {α}_{1} - {α}_{2} ) \times Δ T \times E} \qquad [ TC INDEX 1 ]$$

wherein, U_{T} refers to toughness of the insulating material, α₁ refers to a thermal expansion coefficient of the insulating material, a₂ refers to a thermal expansion coefficient of the conductive material surrounded by the insulating material, ΔT refers to a temperature change, and E refers to Young's modulus, which is an elastic modulus of the insulating material.

According to some example embodiments, cracks are significantly reduced by the TC index 1 when each of the first redistribution insulating layer 310 and the second redistribution insulating layer 410 is formed of the insulating material, and each of the first redistribution pattern 330 and the second redistribution pattern 430 is formed of the conductive material.

Here, the insulating material may include, for example, a photo-imageable dielectric (PID) material or photosensitive polyimide (PSPI). In addition, the PID material may include, for example, any one selected from polyhydroxystyrene (PHS), polybenzoxazole (PBO), and polyimide (PI). In addition, PI may include a negative photosensitive insulating material or a positive photosensitive insulating material. However, the insulating material is not limited to the above materials.

Here, the conductive material forming each of the first redistribution pattern 330 and the second redistribution pattern 430 may include, for example, a metal such as Cu, Al, W, Ti, Ta, In, Mo, Mn, Co, Sn, Ni, Mg, Re, Be, Ga, or Ru or an alloy thereof. However, the inventive concepts are not limited thereto. In general, each of the first redistribution pattern 330 and the second redistribution pattern 430 may include Cu.

Here, U_{T} may be about or exactly 1 mJ/mm³ to about or exactly 110 mJ/mm³, α₁ may be about or exactly 40 ppm/° C. to about or exactly 70 ppm/° C., α₂ may be about or exactly 16.7 ppm/° C., which is a thermal expansion coefficient of Cu, ΔT may be about or exactly 175° C. or about or exactly 215° C., and E may be about or exactly 2 Gpa to about or exactly 4 Gpa.

The value of ΔT may vary under a stress condition and an extreme condition. For example, the stress condition refers to a temperature characteristic test according to a temperature change from about or exactly −55° C. to about or exactly 120° C., and the extreme condition refers to a temperature characteristic test according to a temperature change from about or exactly −65° C. to about or exactly 150° C.

In some example embodiments, each of the first redistribution insulating layer 310 and the second redistribution insulating layer 410 may include an insulating material satisfying that K is 20 or more in TC index 2 below.

$$K = \frac{{U}_{T}}{( {α}_{1} - {α}_{2} ) \times Δ T \times E} \times \frac{{d}_{1}}{{d}_{2}} \qquad [ TC INDEX 2 ]$$

wherein, U_{T} refers to toughness of the insulating material, a refers to a thermal expansion coefficient of the insulating material, α₂ refers to a thermal expansion coefficient of the conductive material surrounded by the insulating material, ΔT refers to a temperature change, E refers to an elastic modulus of the insulating material, d₁ refers to a vertical distance from a bottom surface of a semiconductor chip to top surfaces of external connection terminals, and d₂ refers to a vertical distance from a bottom surface of a semiconductor chip to the bottom surface of the first insulating layer 312 or the second insulating layer 314. Here, d₂ may refer to a bottom surface in each insulating layer when the insulating material includes a plurality of insulating layers.

For example, in FIG. 2, d₁ represents a vertical distance from the bottom surface of the first semiconductor chip 100 to the top surfaces of the external connection terminals 600, d₂ represents a vertical distance from the bottom surface of the first semiconductor chip 100 to the bottom surface of the first insulating layer 312, and d₃ represents a vertical distance from the bottom surface of the first semiconductor chip 100 to the bottom surface of the second insulating layer 314. That is, d₃ may be substituted for d₂ in the TC index 2.

TABLE 1

| | | PE [symbol] | P [symbol] | | PI | PI | |
|---|---|---|---|---|---|---|---|
| Item | Unit* | Positive | Positive | | Positive | Negative | |
| CTE | pp [symbol] /° C. | 44 | 46 | | 84 | [symbol] | |
| Modulus | Gpa | 2.5 | 2.1 | 2.1 | 2.5 | 3.9 | 3.9 |
| Toughness | [symbol] /mm³ | 2 | 20 | 20 | 19 | 108 | 108 |
| Elongation | % | 3 | 18 | 18 | 16 | 62 | 62 |
| Distance | [symbol] | 80 | 80 | 80 | 80 | 80 | 80 |
| from chip | | | | | | | |
| to ball | | | | | | | |
| Distance | [symbol] | 40 | 40 | 65 | 45 | 40 | 75 |
| from chip | | | | | | | |
| to PTD | | | | | | | |
| TC Index | | 4 | 3 [symbol] | 23 | 14 | 7 [symbol] | 42 |

*at −55° C. [symbol]
indicates data missing or illegible when filed

In some example embodiments, according to Table 1 and FIG. 3, it may be noted that occurrence of cracks is reduced in the insulating material satisfying that K is 20 or more (for example, about or exactly 20 to about or exactly 100) in the TC index 2. As such, it may be noted that occurrence of cracks is significantly reduced in the insulating material satisfying that K is 40 or more (for example, about or exactly 40 to about or exactly 100) in the TC index 2.

If the insulating material is selected based on K according to the TC index 2, it may be concluded that it is desirable to use negative photosensitive PI. That is, it may be noted that negative photosensitive PI is a material forming each of the first redistribution insulating layer 310 and the second redistribution insulating layer 410 and has high reliability.

In this way, through quantified values for various materials forming the first redistribution structure 300 and the second redistribution structure 400, K according to the TC index (the TC indices 1 and 2 are collectively referred to hereinafter as the same) may be obtained.

As a result, reliability of the semiconductor package 1000 according to the inventive concepts are improved by forming the first redistribution insulating layer 310 included in the first redistribution structure 300 and the second redistribution insulating layer 410 included in the second redistribution structure 400 of an insulating material (e.g., an optimal insulating material) that may prevent or reduce physical damage in consideration of various physical properties according to the TC index.

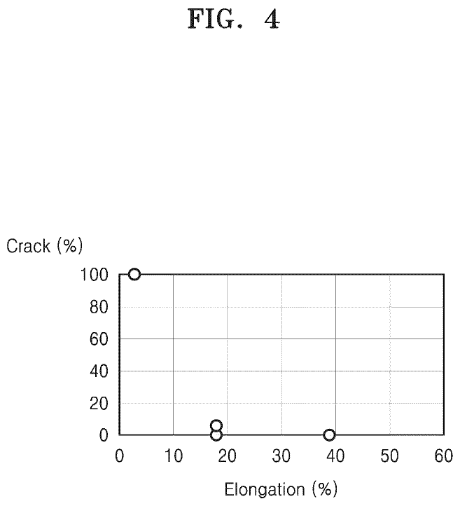

FIGS. 4 to 6 are graphs illustrating a degree of crack occurrence according to various physical properties of an insulating material forming an insulating layer included in a redistribution structure.

Referring to FIGS. 4 to 6, a crack occurrence rate according to elongation, a crack occurrence rate according to fracture resistance, and a crack occurrence rate according to the TC index of the inventive concepts are illustrated, respectively.

In FIG. 4, the elongation is measured under the condition that the insulating material is about −55° C. (the lowest temperature under the stress condition). Examining the crack occurrence rate according to the elongation, it may be noted that the crack occurrence rate is significantly reduced as the elongation, which is a physical property of the insulating material, increases. That is, when the elongation (unit: %) is about or exactly 2%, about or exactly 18%, and about or exactly 40%, a crack occurrence frequency (unit: %) is measured to be about or exactly 100%, about or exactly 0% to about or exactly 8%, and about or exactly 0%.

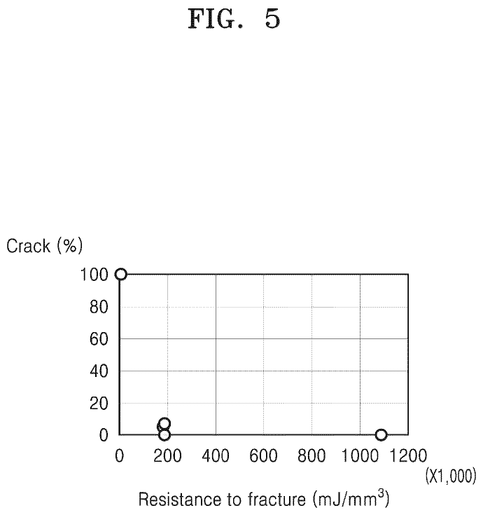

In FIG. 5, the fracture resistance is measured under the condition that the insulating material is about −55° C. (the lowest temperature under the stress condition). Examining the crack occurrence rate according to the fracture resistance, it may be noted that the crack occurrence rate is significantly reduced as the fracture resistance, which is a physical property of the insulating material, increases. That is, when the fracture resistance (unit: mJ/mm³) is about or exactly 0 mJ/mm³, about or exactly 200,000 mJ/mm³, and about or exactly 1,080,000 mJ/mm³, the crack occurrence frequency (unit: %) is about or exactly 100%, about or exactly 0% to about or exactly 10%, and about or exactly 0%. Here, the fracture resistance may be applied as substantially the same physical property as toughness.

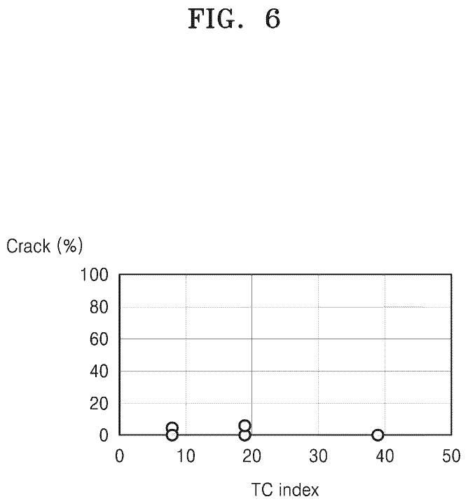

In FIG. 6, the TC index according to the inventive concepts are measured under the condition that the insulating material is about −55° C. (the lowest temperature under the stress condition). Examining the crack occurrence rate according to the TC index according to the inventive concepts, it may be noted that the crack occurrence rate is significantly reduced as the TC index according to the inventive concepts of the insulating material increases. That is, when the TC index according to the inventive concepts (unit: arbitrary unit) is about or exactly 8%, about or exactly 19%, and about or exactly 39%, the crack occurrence frequency (unit: %) is measured to be about or exactly 0% to about or exactly 6%, about or exactly 0% to about or exactly 8%, and about or exactly 0%.

That is, reliability of the semiconductor package 1000 (refer to FIG. 1) is improved by forming the first redistribution insulating layer 310 included in the first redistribution structure 300 and the second redistribution insulating layer 410 included in the second redistribution structure 400 of an insulating material (e.g., an optimal insulating material) that may prevent or reduce physical damage in consideration of various physical properties according to the TC index.

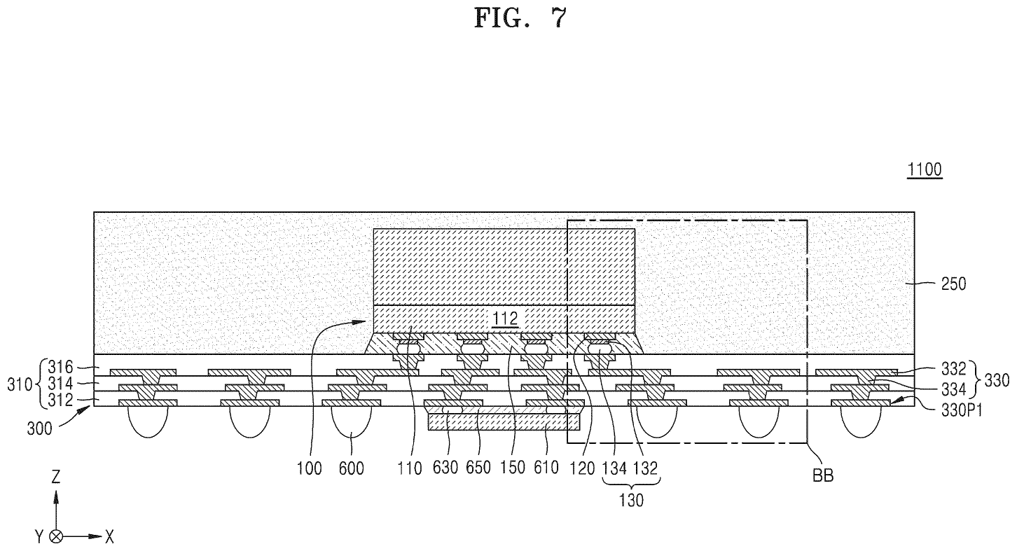

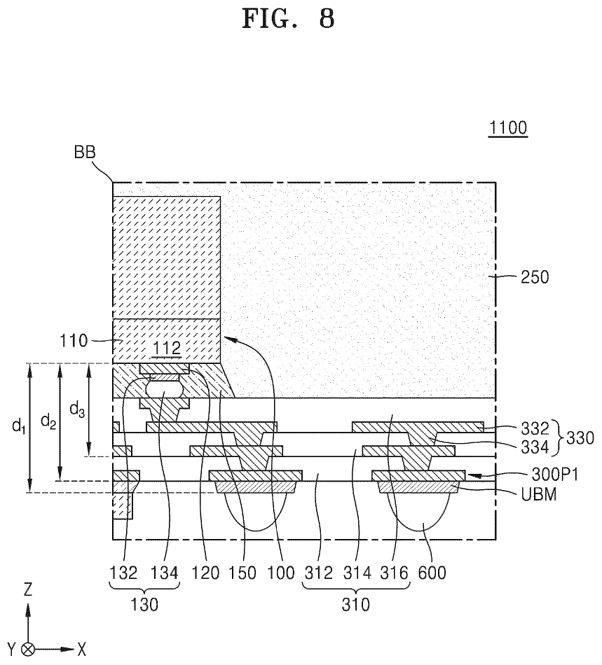

FIG. 7 is a cross-sectional view illustrating main components of a semiconductor package 1100 according to some example embodiments. FIG. 8 is an enlarged cross-sectional view illustrating the portion BB of FIG. 7.

Most of components constituting the semiconductor package 1100 described below and materials forming the components are substantially the same or similar to those previously described in FIGS. 1 to 3. Therefore, for convenience sake, differences from the semiconductor package 1000 described above are mainly described.

Referring to FIGS. 7 and 8, the semiconductor package 1100 may include a first semiconductor chip 100, a first redistribution structure 300 arranged under the first semiconductor chip 100, and an encapsulant 250 surrounding the first semiconductor chip 100 on a top surface of the first redistribution structure 300.

The semiconductor package 1100 may include a fan out semiconductor package in which a horizontal width and a horizontal area of the first redistribution structure 300 are greater than a horizontal width and a horizontal area of the first semiconductor chip 100. In some example embodiments, the semiconductor package 1100 may include a fan-out wafer level package or a fan-out panel level package.

The first redistribution structure 300 may include a first redistribution insulating layer 310 and a plurality of first redistribution patterns 330. The first redistribution insulating layer 310 may surround the plurality of first redistribution patterns 330. In some example embodiments, the first redistribution structure 300 may include a plurality of stacked first redistribution insulating layers 310. For example, the plurality of first redistribution insulating layers 310 may sequentially include a first insulating layer 312, a second insulating layer 314, and a third insulating layer 316. However, the inventive concepts are not limited thereto. The first redistribution insulating layer 310 may be formed of, for example, a PID material.

The plurality of first redistribution patterns 330 may include a plurality of first redistribution line patterns 332 and a plurality of first redistribution vias 334. The plurality of first redistribution line patterns 332 may be arranged on at least one of top and bottom surfaces of the first redistribution insulating layer 310. The plurality of first redistribution vias 334 may penetrate the first redistribution insulating layer 310 to be connected to some of the plurality of first redistribution line patterns 332.

Among the plurality of first redistribution patterns 330, some arranged adjacent to a bottom surface of the first redistribution structure 300 may be referred to as a plurality of first bottom surface connection pads 330P1, and some arranged adjacent to a top surface of the first redistribution structure 300 may be referred to as a plurality of first top surface connection pads 330P2.

A plurality of external connection terminals 600 may be attached to the plurality of first bottom surface connection pads 330P1. The plurality of external connection terminals 600 may connect the semiconductor package 1100 to the outside.

In some example embodiments, a plurality of under-bump metals UBM may be arranged between the plurality of first bottom surface connection pads 330P1 and the plurality of external connection terminals 600. That is, the plurality of under-bump metals UBM may be arranged under the plurality of first bottom surface connection pads 330P1, and the plurality of external connection terminals 600 may be arranged under the plurality of under-bump metals UBM.

In some example embodiments, the plurality of external connection terminals 600 may be attached to some of the plurality of first bottom surface connection pads 330P1, and a passive element 610 may be attached to others of the plurality of first bottom connection pads 330P1.

At least one first semiconductor chip 100 may be mounted on the first redistribution structure 300. That is, the first semiconductor chip 100 may include a single chip or a plurality of chips. The first semiconductor chip 100 may include a semiconductor substrate 110 having an active surface and an inactive surface facing each other, a semiconductor device 112 formed on the active surface of the semiconductor substrate 110, and a plurality of chip pads 120 arranged on a first surface of the first semiconductor chip 100.

The plurality of chip connection members 130 may be interposed between the plurality of chip pads 120 of the first semiconductor chip 100 and some of the plurality of first top surface connection pads 330P2 of the first redistribution structure 300. The plurality of chip connection members 130 may include a plurality of bump layers 132 arranged on the plurality of chip pads 120 and a plurality of internal connection terminals 134 covering the plurality of bump layers 132.

An encapsulant 250 may surround the first semiconductor chip 100 on the top surface of the first redistribution structure 300. The encapsulant 250 may configure an exterior of the semiconductor package 1100. For example, the encapsulant 250 may include a molding member including an EMC. The encapsulant 250 may further include a filler.

In some example embodiments, an internal underfill layer 150 surrounding the plurality of chip connection members 130 may be interposed between the first semiconductor chip 100 and the first redistribution structure 300. In some example embodiments, the internal underfill layer 150 may fill a space between the first semiconductor chip 100 and the first redistribution structure 300 and may partially cover lower sides of the first semiconductor chip 100.

In some example embodiments, the first redistribution insulating layer 310 may include an insulating material satisfying that K is 20 or more in the TC index 1 below.

$$K = \frac{{U}_{T}}{( {α}_{1} - {α}_{2} ) \times Δ T \times E} \qquad [ TC INDEX 1 ]$$

wherein, U_{T} refers to toughness of the insulating material, α₁ refers to a thermal expansion coefficient of the insulating material, α₂ refers to a thermal expansion coefficient of the conductive material surrounded by the insulating material, ΔT refers to a temperature change, and E refers to an elastic modulus of the insulating material.

In some example embodiments, cracks are significantly reduced by the TC index 1 when the first redistribution insulating layer 310 is formed of the insulating material, and the first redistribution pattern 330 is formed of the conductive material.

Here, the insulating material may include, for example, a PID material or PSPI. In addition, the PID material may include, for example, any one selected from PHS, PBO, and PI. In addition, PI may include a negative photosensitive insulating material or a positive photosensitive insulating material. However, the insulating material is not limited to the above materials.

Here, the conductive material forming the plurality of first redistribution patterns 330 may include, for example, a metal such as Cu, Al, W, Ti, Ta, In, Mo, Mn, Co, Sn, Ni, Mg, Re, Be, Ga, or Ru and/or an alloy thereof. However, the inventive concepts are not limited thereto. In general, the plurality of first redistribution patterns 330 may include Cu.

Here, Ur may be about or exactly 1 mJ/mm³ to about or exactly 110 mJ/mm³, α₁ may be about or exactly 40 ppm/° C. to about or exactly 70 ppm/° C., α₂ may be about or exactly 16.7 ppm/° C., which is a thermal expansion coefficient of Cu, ΔT may be about or exactly 175° C. or about or exactly 215° C., and E may be about or exactly 2 Gpa to about or exactly 4 Gpa.

In some example embodiments, the first redistribution insulating layer 310 may include an insulating material satisfying that K is 20 or more (for example, 20 to 100) in the TC index 2 below.

$$K = \frac{{U}_{T}}{( {α}_{1} - {α}_{2} ) \times Δ T \times E} \times \frac{{d}_{1}}{{d}_{2}} \qquad [ TC INDEX 2 ]$$

wherein, U_{T} refers to toughness of the insulating material, a refers to a thermal expansion coefficient of the insulating material, α₂ refers to a thermal expansion coefficient of the conductive material surrounded by the insulating material, ΔT refers to a temperature change, E refers to an elastic modulus of the insulating material, d₁ refers to a vertical distance from a bottom surface of a semiconductor chip to top surfaces of external connection terminals, and d₂ refers to a vertical distance from a bottom surface of a semiconductor chip to the bottom surface of the first insulating layer 312 or the second insulating layer 314. Here, d₂ may refer to a bottom surface in each insulating layer when the insulating material includes a plurality of insulating layers.

For example, in FIG. 8, d₁ represents a vertical distance from the bottom surface of the first semiconductor chip 100 to the top surfaces of the external connection terminals 600, d₂ represents a vertical distance from the bottom surface of the first semiconductor chip 100 to the bottom surface of the first insulating layer 312, and d₃ represents a vertical distance from the bottom surface of the first semiconductor chip 100 to the bottom surface of the second insulating layer 314. That is, d₃ may be substituted for d₂ in the TC index 2.

As a result, reliability of the semiconductor package 1100 according to the inventive concepts are improved by forming the first redistribution insulating layer 310 included in the first redistribution structure 300 of an insulating material (e.g., an optimal insulating material) that may prevent or reduce physical damage in consideration of various physical properties according to the TC index.

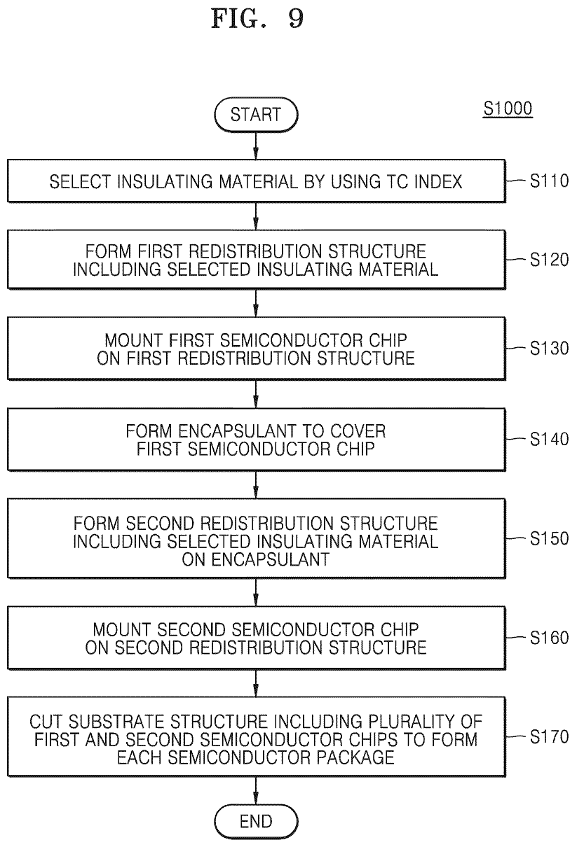

FIG. 9 is a flowchart illustrating a method of manufacturing a semiconductor package according to some example embodiments.

Referring to FIG. 9, the method S1000 of manufacturing a semiconductor package may include operations S110 to S170.

In cases in which some example embodiments may be implemented differently, a specific process order may be performed differently from a described order. For example, two processes described in succession may be performed substantially at the same time, or may be performed in an order opposite to the order in which the processes are described.

A semiconductor package manufacturing method S1000 according to the inventive concepts may include selecting an insulating material by using a TC index in operation S110, forming a first redistribution structure including the selected insulating material in operation S120, mounting a first semiconductor chip on the first redistribution structure in operation S130, forming an encapsulant to cover the first semiconductor chip in operation S140, forming a second redistribution structure including the selected insulating material on the encapsulant in operation S150, mounting a second semiconductor chip on the second redistribution structure in operation S160, and forming each semiconductor package by cutting a substrate structure including the plurality of first and second semiconductor chips in operation S170.

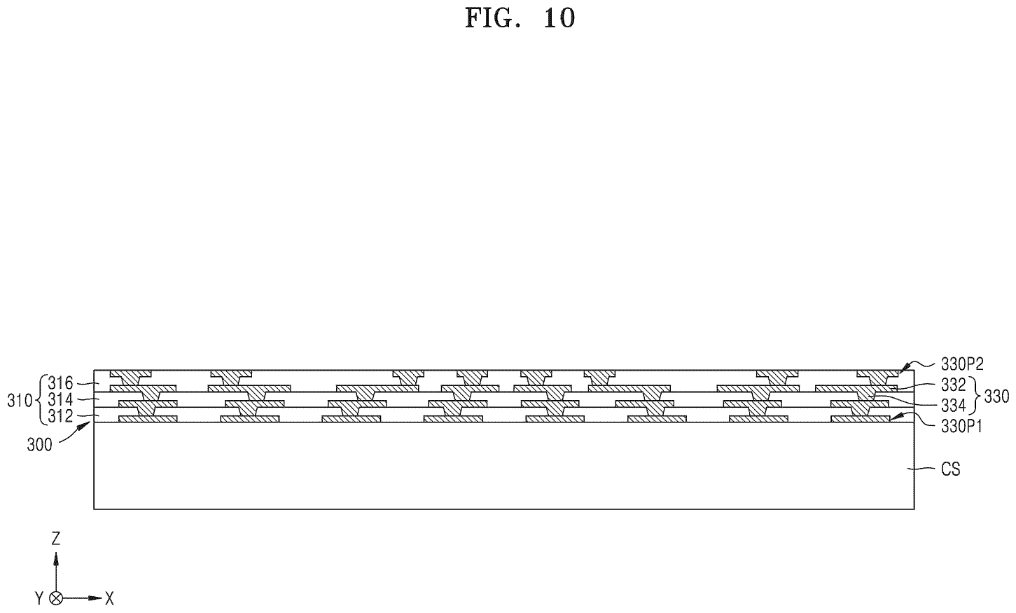

Technical features of each of the operations S110 to S170 will be described in detail with reference to FIGS. 10 to 22 described later.

FIGS. 10 to 22 are cross-sectional views illustrating a method of manufacturing a semiconductor package according to some example embodiments in a process order.

Referring to FIG. 10, the first redistribution structure 300 including the first redistribution insulating layer 310, and the plurality of first redistribution patterns 330 including the plurality of first redistribution line patterns 332 and the plurality of first redistribution vias 334 is formed on a carrier substrate CS.

The insulating material forming the first redistribution insulating layer 310 may be selected as an insulating material (e.g., an optimal insulating material) that may prevent or reduce physical damage in consideration of various physical properties according to the TC index of the inventive concepts.

The carrier substrate CS may include a semiconductor substrate, a glass substrate, a ceramic substrate, or a plastic substrate. In some example embodiments, a release film may be attached onto the carrier substrate CS to form the first redistribution structure 300.

The plurality of first redistribution line patterns 332 may be formed on the carrier substrate CS. The plurality of first redistribution line patterns 332 formed on the carrier substrate CS may include the plurality of first bottom connection pads 330P1.

Next, after forming a first preliminary redistribution insulating layer covering the plurality of first redistribution line patterns 332 on the carrier substrate CS, a part of the first preliminary redistribution insulating layer may be removed by an exposure process and a development process to form the first insulating layer 312 having a plurality of first via holes. The plurality of first via holes may be formed so that a horizontal width decreases from a top surface to a bottom surface of the first insulating layer 312. In some example embodiments, the plurality of first bottom surface connection pads 330P1 and the bottom surface of the first insulating layer 312 may be coplanar.

Next, after a first redistribution conductive layer is formed on the second insulating layer 314, the first redistribution conductive layer may be patterned to form the plurality of first redistribution patterns 330 including the plurality of first redistribution line patterns 332 and the plurality of first redistribution vias 334. The plurality of first redistribution vias 334 of the plurality of first redistribution patterns 330 may fill the plurality of first via holes, and the plurality of first redistribution line patterns 332 of the plurality of first redistribution patterns 330 may be above a top surface of the second insulating layer 314.

Next, the first redistribution structure 300 may be formed by forming the third insulating layer 316 and the plurality of first redistribution patterns 330. The plurality of first redistribution line patterns 332 arranged on the top surface of the first redistribution structure 300 may include the plurality of first top surface connection pads 330P2. In some example embodiments, when the first redistribution insulating layer 310 sequentially includes the first insulating layer 312, the second insulating layer 314, and the third insulating layer 316, the plurality of first top surface connection pads 330P2 may include the plurality of first redistribution line patterns 332 arranged on a top surface of the third insulating layer 316.

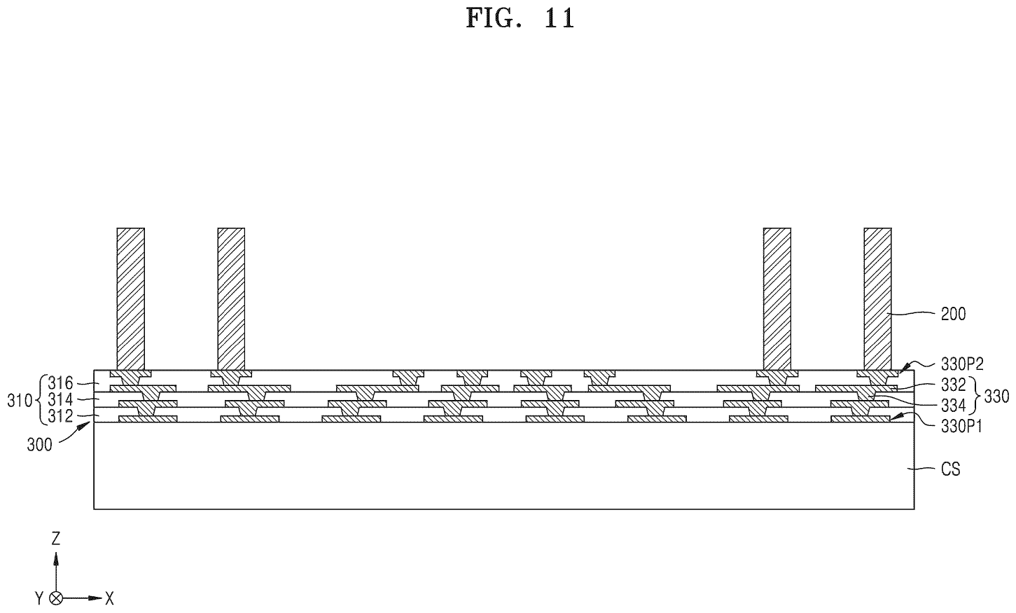

Referring to FIG. 11, the plurality of conductive posts 200 electrically connected to the plurality of first top surface connection pads 330P2 arranged in the outer region of the first redistribution structure 300 are formed.

The plurality of conductive posts 200 may be formed by electroplating. The plurality of conductive posts 200 satisfying a desired shape may be formed by an exposure process and a development process using photoresist (not shown) and a single plating process. In some example embodiments, the conductive material may include Cu or a Cu alloy. However, the inventive concepts are not limited thereto.

For example, the plurality of first top surface connection pads 330P2 may function as seed layers for forming the plurality of conductive posts 200. That is, when the plurality of conductive posts 200 are formed by an electroplating process, the plurality of first top surface connection pads 330P2 provide a path through which current may flow so that the plurality of conductive posts 200 may be formed on the plurality of first top surface connection pads 330P2.

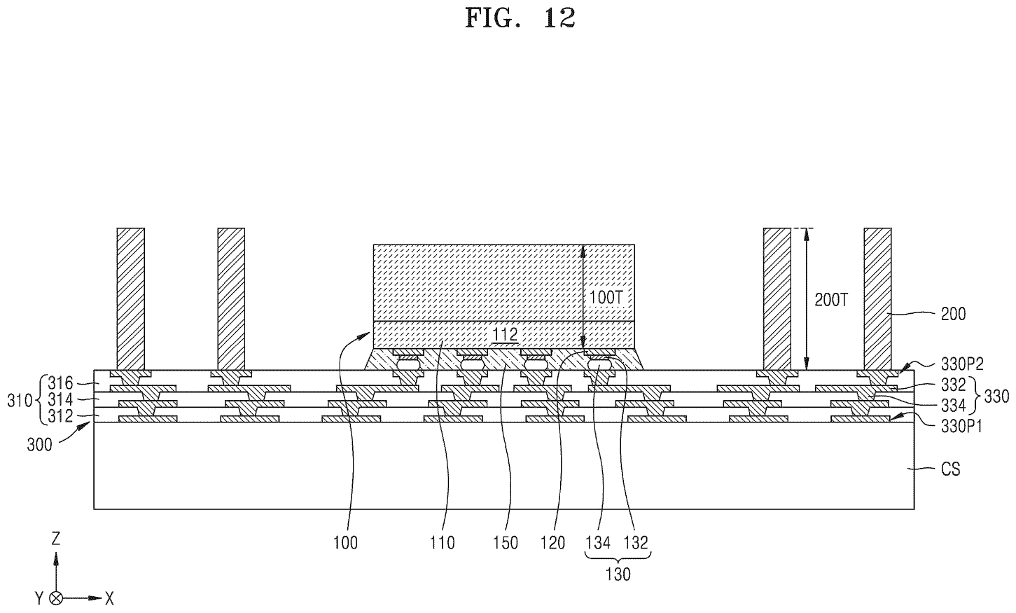

Referring to FIG. 12, the first semiconductor chip 100 including the plurality of chip pads 120 is mounted on the first redistribution structure 300.

The first semiconductor chip 100 may be mounted on the first redistribution structure 300 so that the plurality of chip connection members 130 are interposed between the plurality of chip pads 120 and some of the plurality of first top surface connection pads 330P2 of the first redistribution structure 300.

The first semiconductor chip 100 may be mounted on a chip mounting region of the first redistribution structure 300 to be apart from the plurality of conductive posts 200 in the horizontal direction. For example, the plurality of chip connection members 130 including the plurality of bump layers 132 and the plurality of internal connection terminals 134 covering the plurality of bump layers 132 may be formed on the plurality of chip pads 120 of the first semiconductor chip 100, and the first semiconductor chip 100 in which the plurality of chip connection members 130 are formed may be mounted on the first redistribution structure 300.

The internal underfill layer 150 may fill a space between the first semiconductor chip 100 and the first redistribution structure 300. The internal underfill layer 150 may surround the plurality of chip connection members 130.

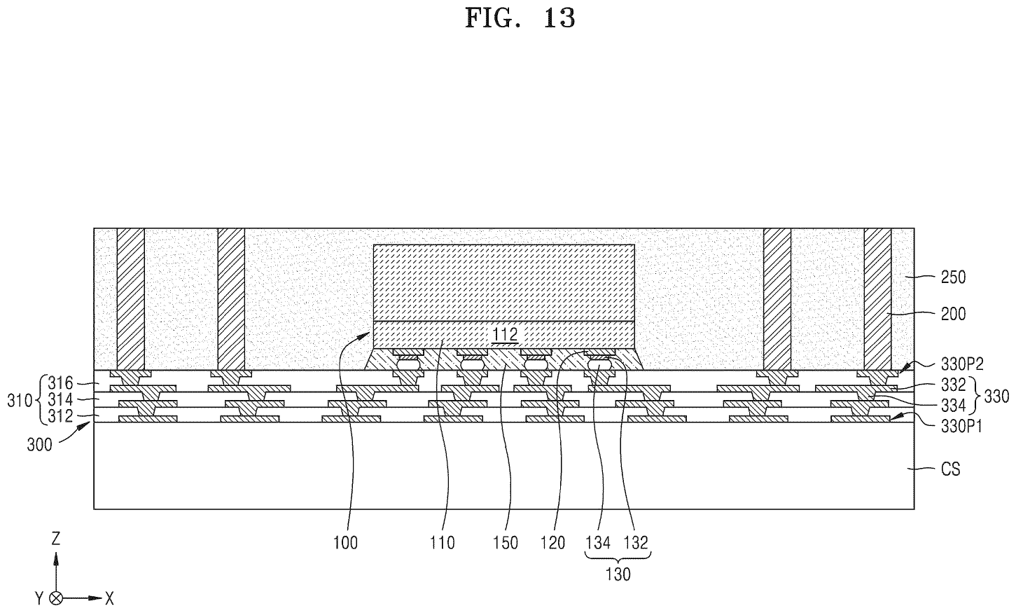

Referring to FIG. 13, the encapsulant 250 covering the first semiconductor chip 100 and the plurality of conductive posts 200 is formed.

The encapsulant 250 may be formed to have a top surface at a vertical level higher than the top of the plurality of conductive posts 200 so as to cover all top surfaces of the plurality of conductive posts 200.

Next, a part of the encapsulant 250 is removed so that the plurality of conductive posts 200 are exposed. That is, an upper portion of the encapsulant 250 may be partially removed by a chemical mechanical polishing (CMP) process. The encapsulant 250 may include a molding member including an EMC.

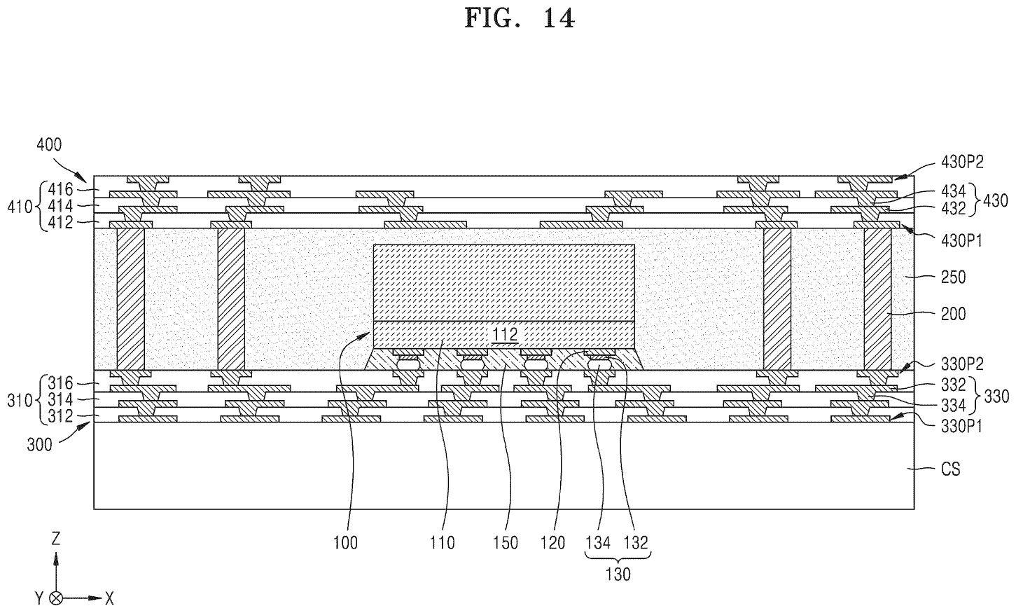

Referring to FIG. 14, the second redistribution structure 400 including the second redistribution insulating layer 410 and the plurality of second redistribution patterns 430 including the plurality of second redistribution line patterns 432 and the plurality of second redistribution vias 434 is formed on the plurality of conductive posts 200 and the encapsulant 250.

The insulating material forming the second redistribution insulating layer 410 may be selected as an insulating material (e.g., an optimal insulating material) that may prevent or reduce physical damage in consideration of various physical properties according to the TC index of the inventive concepts.

After forming a second preliminary redistribution insulating layer on the plurality of conductive posts 200 and the encapsulant 250, a part of the second preliminary redistribution insulating layer may be removed by an exposure process and a development process to form the fourth insulating layer 412 having a plurality of second via holes. In some example embodiments, the plurality of second bottom surface connection pads 430P1 and the bottom surface of the fourth insulating layer 412 may be coplanar.

The plurality of second via holes may be formed so that a horizontal width decreases from a top surface to a bottom surface of the fourth insulating layer 412. Next, after a second redistribution conductive layer is formed on the fifth insulating layer 414, the second redistribution conductive layer may be patterned to form the plurality of second redistribution patterns 430 including the plurality of second redistribution line patterns 432 and the plurality of second redistribution vias 434.

The plurality of second redistribution vias 434 formed on the plurality of conductive posts 200 may include the plurality of second bottom surface connection pads 430P1. The plurality of second redistribution vias 434 of the plurality of second redistribution patterns 430 may fill the plurality of second via holes, and the plurality of second redistribution line patterns 432 of the plurality of second redistribution patterns 430 may be above a top surface of the fifth insulating layer 414.

Next, the second redistribution structure 400 may be formed by forming the sixth insulating layer 416 and the plurality of second redistribution patterns 430. The plurality of second redistribution line patterns 432 arranged on the top surface of the second redistribution structure 400 may include the plurality of second top surface connection pads 430P2. In some example embodiments, when the second redistribution insulating layer 410 sequentially includes the fourth insulating layer 412, the fifth insulating layer 414, and the sixth insulating layer 416, the plurality of second top surface connection pads 430P2 may include the plurality of second redistribution line patterns 432 arranged on a top surface of the sixth insulating layer 416.

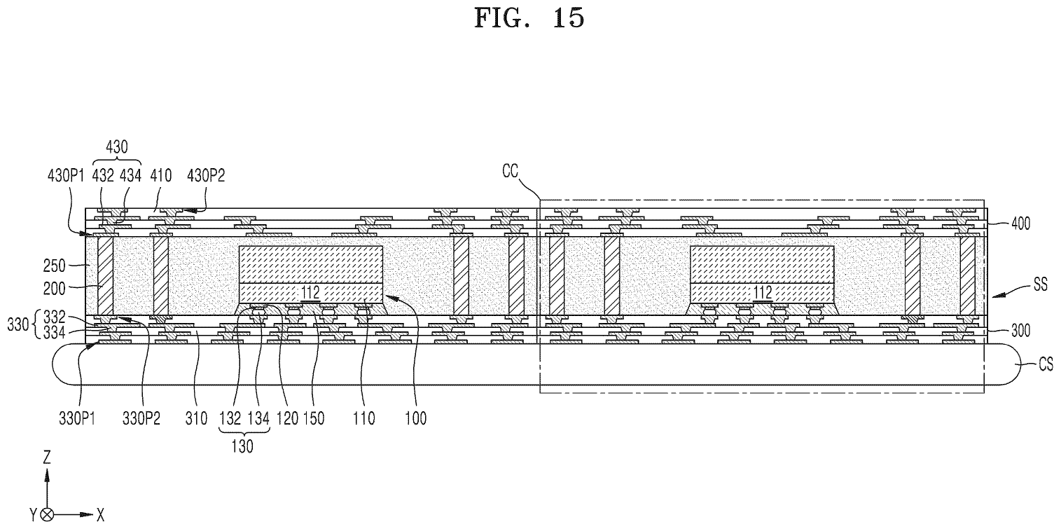

Referring to FIG. 15, a substrate structure SS formed on the carrier substrate CS may be prepared.

For convenience sake, the manufacturing processes of one first semiconductor chip 100 have been mainly described. However, substantially, a plurality of first semiconductor chips 100 may be arranged on the carrier substrate CS side by side or in a matrix to form the substrate structure SS. That is, the manufacturing processes are described in FIGS. 10 to 14, focusing on the portion CC of FIG. 15.

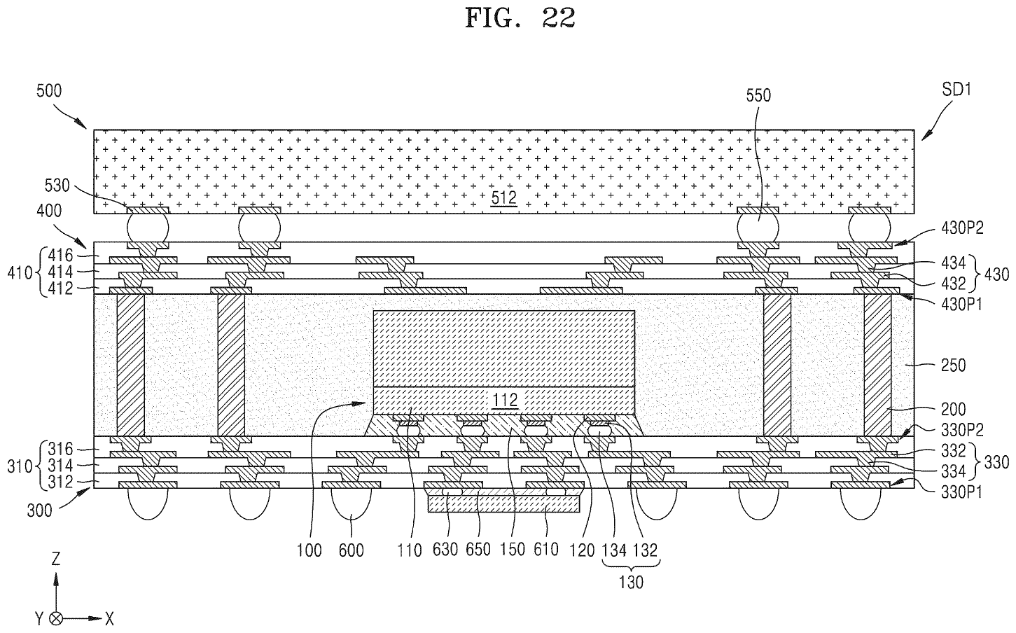

Therefore, the manufacturing processes are described focusing on the process of manufacturing the substrate structure SS including the plurality of first semiconductor chips 100 into each semiconductor package 1000 (refer to FIG. 22).

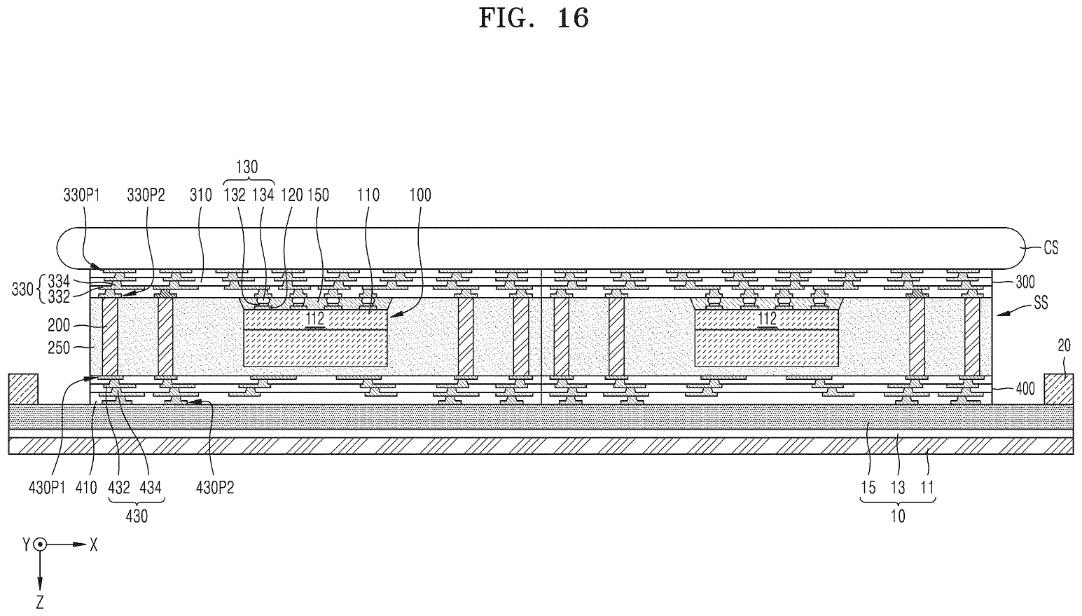

Referring to FIG. 16, an exposed surface of the substrate structure SS may be attached to a dicing film 10.

The dicing film 10 may include a base layer 11, an intermediate layer 13 on the base layer 11, and an adhesive layer 15 on the intermediate layer 13. Here, the dicing film 10 may have a first diameter. The first diameter may be greater than a second diameter of the substrate structure SS. The second diameter as a diameter of a wafer constituting the substrate structure SS may correspond to, for example, about or exactly 300 mm (or, for example, about or exactly 12 inches) or about or exactly 450 mm (or, for example, about or exactly 18 inches).

The exposed surface of the substrate structure SS to which the carrier substrate CS is attached may be mounted to adhere onto the adhesive layer 15 of the dicing film 10. As illustrated in FIG. 16, an edge of the adhesive layer 15 of the dicing film 10 may be fixed to a lower portion of a frame 20. The frame 20 may have a circular ring shape. However, the inventive concepts are not limited thereto. When the substrate structure SS to which the carrier substrate CS is attached is attached onto the adhesive layer 15 of the dicing film 10, the second redistribution structure 400 formed in the substrate structure SS may be attached to face the adhesive layer 15.

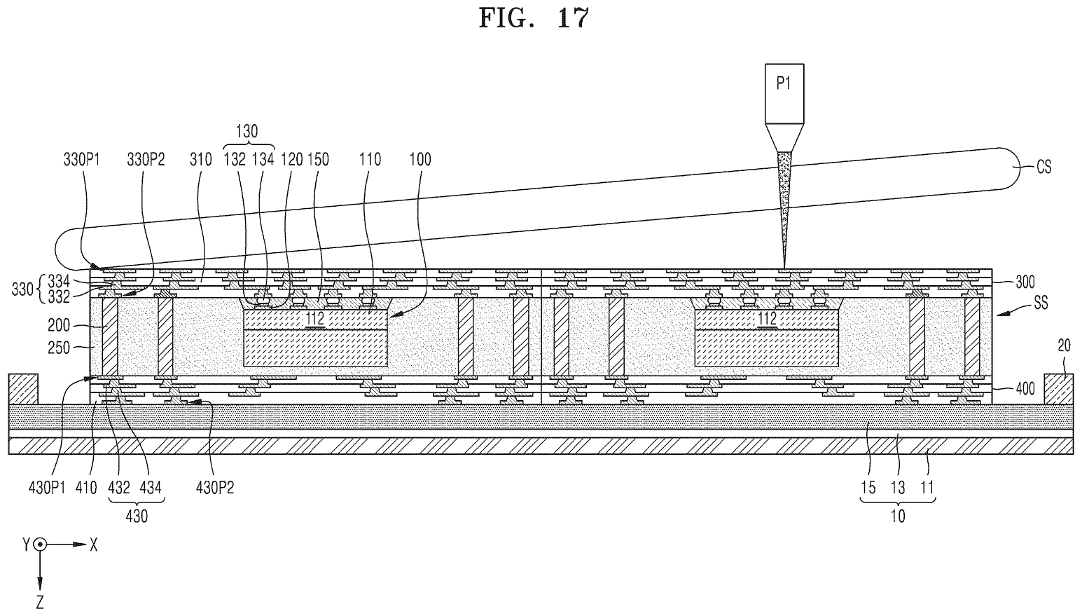

Referring to FIG. 17, the carrier substrate CS may be separated from the substrate structure SS.

In order to separate and remove the carrier substrate CS, a laser P1 may be irradiated onto the carrier substrate CS. A bonding force between the substrate structure SS and the carrier substrate CS may be weakened by irradiation of the laser P1, and the carrier substrate CS may be completely separated.

An adhesive layer (not shown) may be arranged between the carrier substrate CS and the substrate structure SS to facilitate separation of the carrier substrate CS. The adhesive layer may be in a liquid or gel form that may be easily deformed by an amount of heat (for example, a predetermined or desired amount of heat) caused by irradiation of the laser P1.

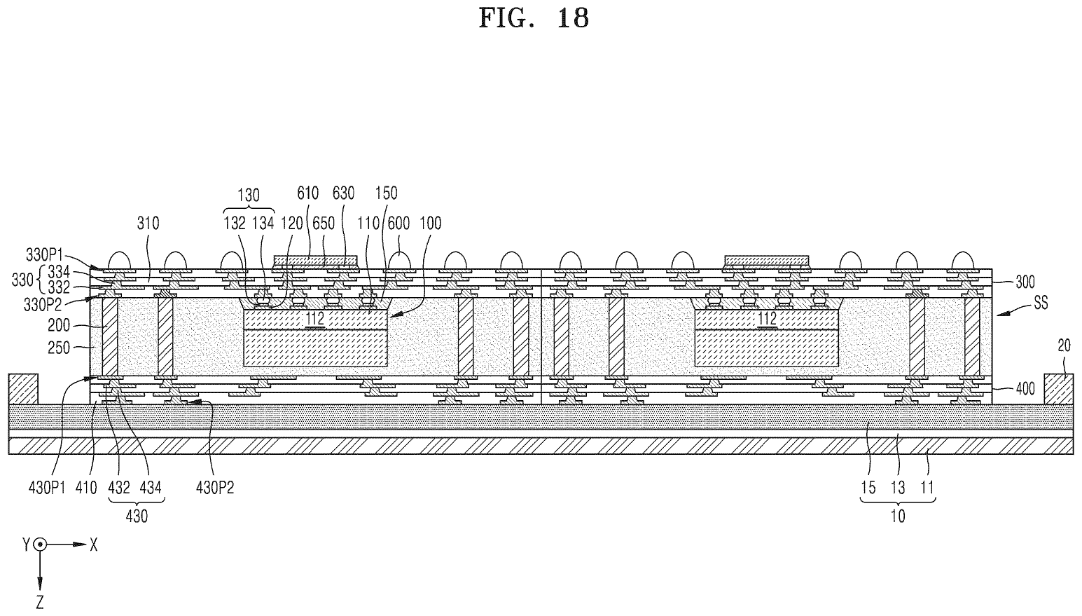

Referring to FIG. 18, the plurality of external connection terminals 600 may be attached to some of the plurality of first bottom surface connection pads 330P1, and the passive element 610 may be attached to the others of the plurality of first bottom surface connection pads 330P1.

In order to attach the plurality of external connection terminals 600 and the passive element 610 to the plurality of first bottom surface connection pads 330P1, a reflow process may be performed. After solder forming the plurality of external connection terminals 600 is melted by the reflow process, the solder may be arranged in a ball shape on the plurality of first bottom surface connection pads 330P1 due to surface tension without collapsing. In some example embodiments, an intermetallic compound may be formed at an interface between the plurality of external connection terminals 600 and the plurality of first bottom surface connection pads 330P1.

Next, a space between the passive element 610 and the first redistribution structure 300 may be filled with the external underfill layer 650. The external underfill layer 650 may surround the sidewalls of the solder bumps 630 arranged under the passive element 610 and may fill a gap between the solder bumps 630 adjacent to each other.

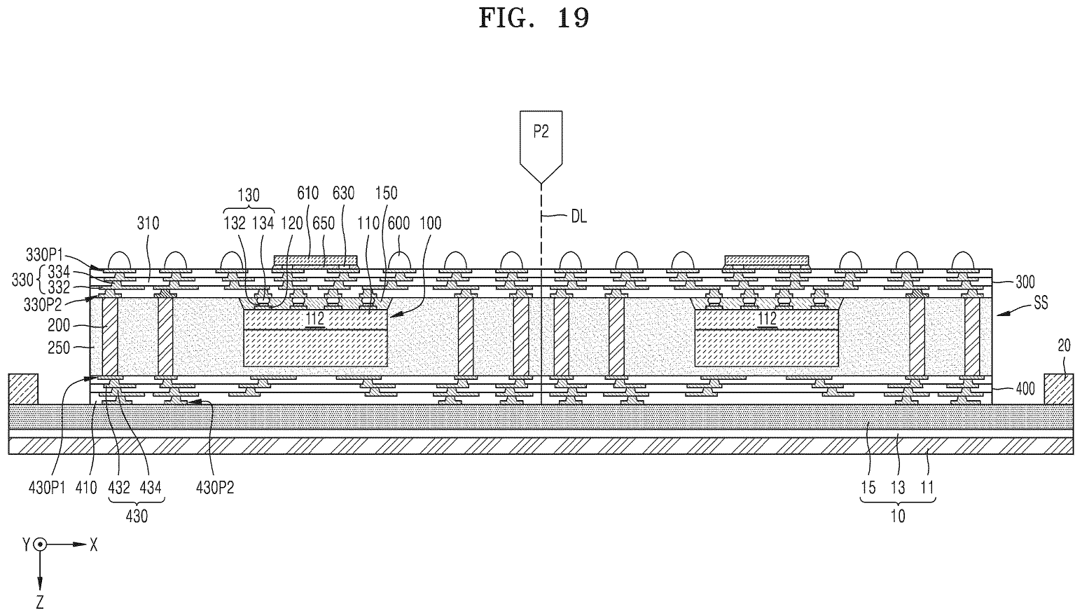

Referring to FIG. 19, various components including the first redistribution structure 300 of the substrate structure SS may be cut P2 along a dicing line DL.

Because the substrate structure SS may include a fan-out wafer level package or a fan-out panel level package, various types of material films including the first redistribution structure 300 may be cut P2 along the dicing line DL to be physically separated into individual semiconductor dies. Although only one dicing line DL is illustrated in the drawing, the inventive concepts are not limited thereto.

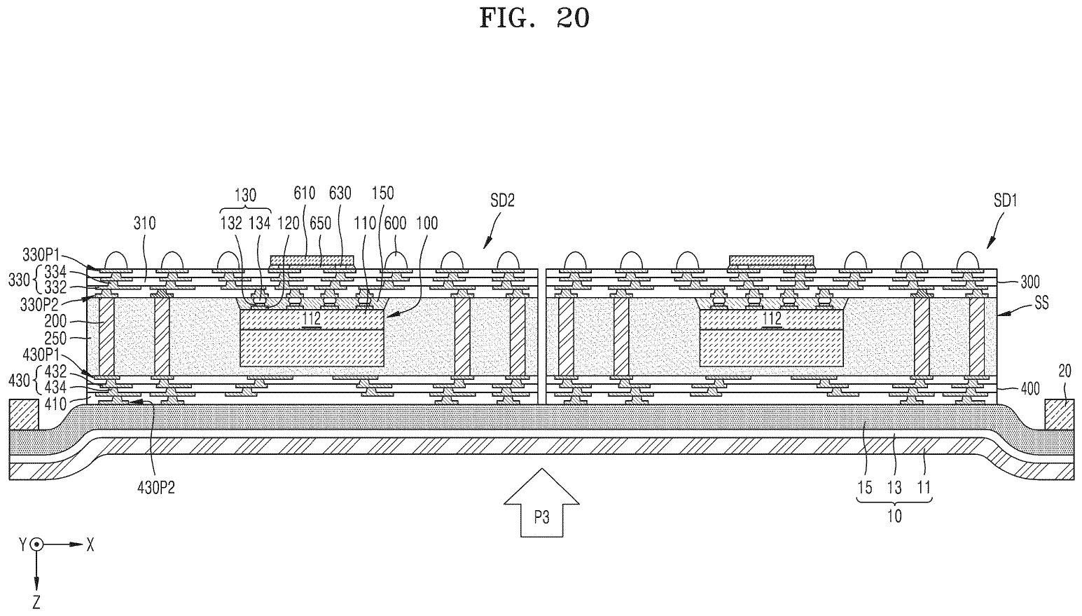

Referring to FIG. 20, pressure P3 may be provided to a bottom of the dicing film 10 to expand a surface area of the dicing film 10.

In some example embodiments, a jig (not shown) may be attached to the bottom of the dicing film 10 and the jig may be pushed up to expand the dicing film 10. That is, the pressure P3 may be provided to the bottom of the dicing film 10.

According to the expansion of the dicing film 10, the substrate structure SS (refer to FIG. 19) may be physically separated into first and second semiconductor dies SD1 and SD2 based on the dicing line DL (refer to FIG. 19). Although only the first and second semiconductor dies SD1 and SD2 are illustrated in the drawing, the number of semiconductor dies is not limited thereto.

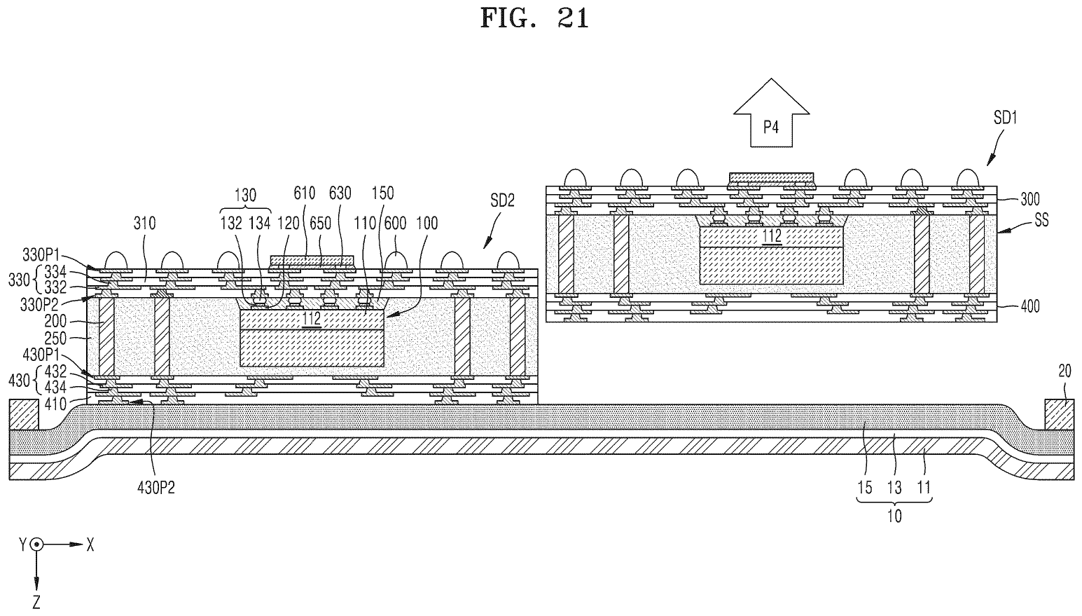

Referring to FIG. 21, the first semiconductor die SD1 may be picked up (P4) from the dicing film 10 by using a pickup device.

In some example embodiments, a wet cleaning process may be performed to remove adhesive residue that may remain on the exposed surface of the dicing film 10 when the dicing film 10 is removed from the first semiconductor die SD1. The wet cleaning process may be performed by using an organic solvent or an inorganic solvent depending on a material of the adhesive layer 15 constituting the dicing film 10.

Referring to FIG. 22, the second semiconductor chip 500 may be mounted to be electrically connected to the second redistribution structure 400 of the first semiconductor die SD1.

The second semiconductor chip 500 may be mounted on the second redistribution structure 400 so that the plurality of second pads 530 face the second redistribution structure 400. The second semiconductor chip 500 may be electrically connected to the plurality of first redistribution patterns 330 of the first redistribution structure 300 through a plurality of internal connection terminals 550 attached to the plurality of second pads 530, the plurality of second redistribution patterns 430, and the plurality of conductive posts 200. In this way, the semiconductor package 1000 may be completed.

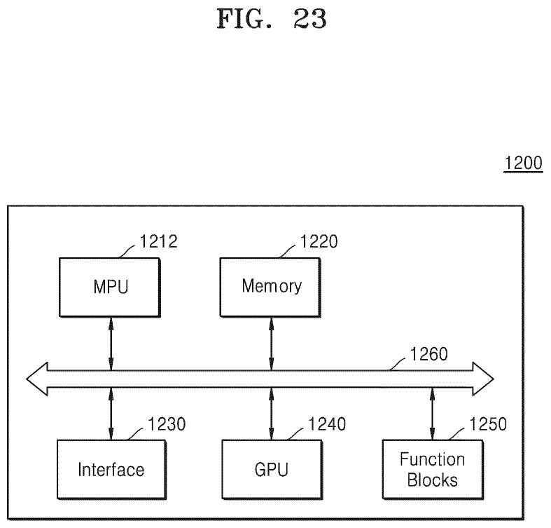

FIG. 23 is a block diagram schematically illustrating a configuration of a semiconductor package 1200 according to some example embodiments.

Referring to FIG. 23, the semiconductor package 1200 may include a micro-processing unit 1210, memory 1220, an interface 1230, a GPU 1240, function blocks 1250, and a bus 1260 connecting the above components to one another.

The semiconductor package 1200 may include both the micro-processing unit 1210 and the GPU 1240, or may include only one of the two.

The micro-processing unit 1210 may include a core and a cache. For example, the micro-processing unit 1210 may include a multi-core. Each core of the multi-core may have the same or different performance. In addition, each core of the multi-core may be activated at the same time or may be activated at different times.

The memory 1220 may store results processed by the function blocks 1250 under the control of the micro-processing unit 1210. The interface 1230 may exchange information or signals with external devices. The GPU 1240 may perform graphic functions. For example, the GPU 1240 may perform video codec or may process 3D graphics. The function blocks 1250 may perform various functions. For example, when the semiconductor package 1200 includes an application processor used in a mobile device, some of the function blocks 1250 may perform a communication function.

The semiconductor package 1200 may include the semiconductor package 1000 described above with reference to FIG. 1 and/or the semiconductor package 1100 described with reference to FIG. 7.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts has been particularly shown and described with reference to example embodiments thereof, it will be understood that various changes in form and details may be made therein without departing from the spirit and scope of the following claims.

What is claimed is:

1. A semiconductor package comprising:
a first redistribution structure including a plurality of first redistribution patterns and a first redistribution insulating layer surrounding the plurality of first redistribution patterns, the plurality of first redistribution patterns having a plurality of first bottom surface connection pads and a plurality of first top surface connection pads;
a first semiconductor chip mounted in a first chip mounting region on the first redistribution structure;
a plurality of first solder bumps attached to the plurality of first bottom surface connection pads under the first redistribution structure;
a second redistribution structure including a plurality of second redistribution patterns and a second redistribution insulating layer surrounding the plurality of second redistribution patterns, the plurality of second redistribution patterns having a plurality of second bottom surface connection pads and a plurality of second top surface connection pads, the second redistribution structure on the first semiconductor chip and the first redistribution structure;
a second semiconductor chip mounted in a second chip mounting region on the second redistribution structure;
a plurality of second solder bumps attached to the plurality of second top surface connection pads between the second redistribution structure and the second semiconductor chip;
a plurality of conductive posts around the first semiconductor chip connecting some of the plurality of first top surface connection pads to some of the plurality of second bottom surface connection pads; and
an encapsulant filling a space between the first redistribution structure and the second redistribution structure and surrounding the plurality of conductive posts and the first semiconductor chip, each of the plurality of first redistribution patterns and the plurality of second redistribution patterns including a conductive material, and
each of the first redistribution insulating layer and the second redistribution insulating layer including an insulating material of which K is 20 to 100 in a TC index according to equation
$$K = \frac{{U}_{T}}{( {α}_{1} - {α}_{2} ) \times Δ T \times E} \qquad [ TC INDEX ]$$
wherein,
U_{T} is toughness of the insulating material,
α₁ is a thermal expansion coefficient of the insulating material,
α₂ refers is a thermal expansion coefficient of the conductive material surrounded by the insulating material,
ΔT is a temperature change, and
E is an elastic modulus of the insulating material.

2. The semiconductor package of claim 1, wherein each of the first redistribution insulating layer and the second redistribution insulating layer comprises a plurality of insulating layers, and a thickness in a vertical direction of each of the plurality of insulating layers is 3 μm to 10 μm.

3. The semiconductor package of claim 1, wherein the insulating material comprises a photo-imageable dielectric (PID) material.

4. The semiconductor package of claim 3, wherein the PID material comprises any one selected from polyhydroxystyrene (PHS), polybenzoxazole (PBO), and polyimide (PI).

5. The semiconductor package of claim 4, wherein the PI comprises a negative photosensitive insulating material or a positive photosensitive insulating material.

6. The semiconductor package of claim 1, wherein the conductive material in each of the plurality of first redistribution patterns and the plurality of second redistribution patterns is copper (Cu).

7. The semiconductor package of claim 1, wherein, in a temperature characteristic test of the semiconductor package, a temperature change is −55° C. to 120° C. or −65° C. to 150° C.

8. The semiconductor package of claim 7, wherein, in the insulating material, the ΔT is 175° C. or 215° C.

9. The semiconductor package of claim 1, wherein, in the insulating material, the E is 2 Gpa to 4 Gpa.

10. The semiconductor package of claim 1, wherein
each of the first redistribution insulating layer and the second redistribution insulating layer comprises a plurality of insulating layers stacked in a vertical direction, and
at least some of the plurality of insulating layers comprise insulating materials having different K values in the TC index.

11. A semiconductor package comprising:
a redistribution structure including a redistribution layer including copper (Cu) and an insulating layer surrounding the redistribution layer;
a semiconductor chip mounted on the redistribution structure and including connection pads;
internal connection terminals between the redistribution structure and the semiconductor chip configured to electrically connect the redistribution layer to the connection pads;
external connection terminals attached under the redistribution structure and electrically connected to the redistribution layer; and
an encapsulant configured to surround the semiconductor chip and the internal connection terminals on the redistribution structure, the insulating layer including an insulating material of which K is 20 to 100 in a TC index according to equation below.
$$K = \frac{{U}_{T}}{( {α}_{1} - {α}_{2} ) \times Δ T \times E} \qquad [ TC INDEX ]$$
wherein,
U_{T} is toughness of the insulating material,
α₁ is a thermal expansion coefficient of the insulating material,
α₂ is a thermal expansion coefficient of copper (Cu),
ΔT is a temperature change, and
E is an elastic modulus of the insulating material.

12. The semiconductor package of claim 11, wherein
the U_{T} is 1 mJ/mm³ to 110 mJ/mm³,
α₁ is 40 ppm/° C. to 70 ppm/° C.,
α₂ is 16.7 ppm/° C.,
the ΔT is 175° C. or 215° C., and
the E is 2 Gpa to 4 Gpa.

13. The semiconductor package of claim 12, wherein the insulating layer comprises a plurality of layers and a thickness in a vertical direction of each of the plurality of layers is 3 μm to 10 μm.

14. The semiconductor package of claim 11, wherein the insulating material comprises a photo-imageable dielectric (PID) material including any one selected from polyhydroxystyrene (PHS), polybenzoxazole (PBO), and polyimide (PI).

15. The semiconductor package of claim 11, wherein
the insulating layer comprises a plurality of layers stacked in a vertical direction, and
at least some of the plurality of layers comprise insulating materials having different K values in the TC index.

16. A semiconductor package comprising:
a redistribution structure including
a first insulating layer,
at least one a second insulating layer on the first insulating layer, and
a plurality of redistribution layers on the first insulating layer and the at least one second insulating layer, the plurality of redistribution layers configured to electrically connect to one another, each of the plurality of redistribution layers includes a conductive material;
a semiconductor chip mounted on the redistribution structure and including connection pads;
internal connection terminals between the redistribution structure and the semiconductor chip configured to electrically connect the plurality of redistribution layers to the connection pads;
external connection terminals attached under the redistribution structure and electrically connected to the plurality of redistribution layers; and
an encapsulant surrounding the semiconductor chip and the internal connection terminals on the redistribution structure, wherein each of the first insulating layer and at least one the second insulating layer includes an insulating material of which K is 20 to 100 in a TC index according to equation below
$$K = \frac{{U}_{T}}{( {α}_{1} - {α}_{2} ) \times Δ T \times E} \times \frac{{d}_{1}}{{d}_{2}} \qquad [ TC INDEX ]$$
wherein,
U_{T} is toughness of the insulating material,
α₁ is a thermal expansion coefficient of the insulating material,
α₂ is a thermal expansion coefficient of the conductive material surrounded by the insulating material,
ΔT is a temperature change,
E is an elastic modulus of the insulating material,
d₁ is a vertical distance from a bottom surface of a semiconductor chip to top surfaces of external connection terminals, and
d₂ is a vertical distance from a bottom surface of a semiconductor chip to a bottom surface of a first insulating layer or a second insulating layer.

17. The semiconductor package of claim 16, wherein an under-bump metal is in the lowermost redistribution layer among the plurality of redistribution layers, and the external connection terminals are attached to the under-bump metal.

18. The semiconductor package of claim 17, wherein the d₁ is greater than or equal to the d₂.

19. The semiconductor package of claim 16, wherein a thickness in a vertical direction of each of the first insulating layer and at least one the second insulating layer is 3 μm to 10 μm.

20. The semiconductor package of claim 19, wherein
the insulating material comprises a photo-imageable dielectric (PID) material including any one selected from polyhydroxystyrene (PHS), polybenzoxazole (PBO), and polyimide (PI), and
the first insulating layer and at least one the second insulating layer include different insulating materials from each other.
